(19) United States
(12) Patent Application Publication
(10) Pub. No.: US 2009/0273014 A1
(43) Pub. Date: Nov. 5, 2009

(54) NONVOLATILE SEMICONDUCTOR MEMORY DEVICE

(75) Inventors: Tsuyoshi ARIGANE, Akishima (JP); Digh HISAMOTO, Kokubunji (JP); Yasuhiro SHIMAMOTO, Tokorozawa (JP); Hideo KASAI, Kokubunji (JP); Ken MATSUBARA, Higashimurayama (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP.

(21) Appl. No.: 12/430,088

(22) Filed: Apr. 26, 2009

(30) Foreign Application Priority Data
May 1, 2008 (JP) JP2008-119490

(51) Int. Cl. H01L 29/788; H01L 29/792

(52) U.S. Cl. 257/315; 257/324; 257/E29.3; 257/E29.309

(57) ABSTRACT

Each of a memory gate, a control gate, a source diffusion layer, and a drain diffusion layer is connected to a control circuit for controlling potential, and the control circuit operates so as to supply a first potential to the memory gate, a second potential to the control gate, a third potential to the drain diffusion layer, and a fourth potential to the source diffusion layer. Here, after setting the memory gate to be in a floating state by shifting a switch transistor from an ON state to an OFF state, the control circuit operates so as to supply a sixth potential which is higher than the second potential to the control gate to make the memory gate have a fifth potential which is higher than the first potential, thereby boosting the memory gate.

### CROSS-REFERENCE TO RELATED APPLICATION

The present application claims priority from Japanese Patent Application No. JP 2008-119490 filed on May 1, 2008, the content of which is hereby incorporated by reference into this application.

### TECHNICAL FIELD OF THE INVENTION

The present invention relates to a nonvolatile semiconductor memory device. More particularly, the present invention relates to a technique effectively applied to a nonvolatile semiconductor memory device having a MONOS (Metal Oxide Nitride Oxide Semiconductor) type memory cell in which a nitride film is used for a charge storing layer.

### BACKGROUND OF THE INVENTION

As a nonvolatile semiconductor memory device which is electrically programmable and erasable, the EEPROM (Electrically Erasable and Programmable Read Only Memory) is currently used. A memory cell of the nonvolatile semiconductor memory device is developed as a high-density memory medium in a device such as a mobile terminal, a digital camera, and a mobile computer card. And, for using the memory cell as the high-density memory medium, a reduction of power consumption is important in addition to scale down of an area size of a semiconductor chip by increasing a degree of integration.

By the way, a flash memory representing the nonvolatile semiconductor memory device embeds a charge pump circuit for generating a memory operating voltage higher than a power supply voltage for programming and erasing information to the memory cell, that is a voltage step-up circuit (booster). In the charge-pump circuit, a field-effect transistor is used for a switch configuring a charge path and a discharge path, and a charge is stored by applying an input power supply from the charge path to a capacitor for charging, and further, another charge is added to the stored charge by applying the input power supply from the discharge path to the capacitor for charging, and then, the added charge is moved to an output capacitor, thereby performing a boost of voltage. However, since the memory operating voltage is determined by the number of steps of the charge-pump circuit, the number of steps is increased as the memory operating voltage is high, and therefore, an area size of the charge-pump circuit becomes large. Accordingly, it is important to perform the memory operation with lowering of the memory operating voltage generated in the charge-pump circuit in order to realize the scaling down of the area size of the semiconductor chip and the reduction of the power consumption.

For example, Japanese Patent Application Laid-Open Publication No. 2006-302411 (Patent Document 1) discloses, for a NAND-type flash memory, a method in which a selected word line is set to be in a floating state after applying a programming voltage to the selected word line, and a boosting voltage is applied to two lines of a programming unselected word line which are adjacent to the selected word line, thereby boosting a potential of the selected word line by a capacitive coupling between the selected word line and the unselected word line.

Also, Japanese Patent Application Laid-Open Publication No. H11-163306 (Patent Document 2) discloses, for the NAND-type flash memory, a method in which a boosting plate is formed on an upper portion of the word line to apply a positive voltage to a boosting gate upon the programming operation, thereby boosting the voltage of the programming selected word line.

Further, Japanese Patent Application Laid-Open Publication No. 2001-060675 (Patent Document 3) and Japanese Patent Application Laid-Open Publication No. 2005-038894 (Patent Document 4) disclose, for a stack-type memory cell having a floating gate, a method in which a diffusion layer for boosting the word line differing from a source and a drain of the memory cell is formed to apply a positive voltage thereto for boosting the word line, thereby boosting the voltage of the programming selected word line.

### SUMMARY OF THE INVENTION

According to boosting methods disclosed in the above-described Patent Documents 1, 2, 3, and 4, since a potential of a desired gate electrode is boosted by the capacitive coupling between gate electrodes which are adjacent to each other, the charge-pump circuit corresponding to a performance of the boosting is unnecessary, thereby capable of scaling down of an area size of a power supply circuit.

However, various technical issues as described below exist in the boosting methods disclosed in the above-described Patent Documents 1, 2, 3, and 4.

In the above-described Patent Document 1, it is considered that, a switch MIS for setting each of the selected word line and the unselected word line to be in a floating and an un-floating state is necessary to any memory cell, and therefore, an area size of an array is increased. And, it is considered that a region of this switch MIS is increased as the number of memory cells connected to a NAND string is increased.

Also, in the above-described Patent Document 2, the boosting plate for performing the boost operation is formed on the upper portion of the word line, and for example, after forming a word line formed of a polysilicon film, a boosting plate formed of a polysilicon film is further required to be formed, and therefore, the number of manufacturing steps is increased.

Further, in the above-described Patent Documents 3 and 4, the diffusion layer for boosting the word line differing from the source and the drain of the memory cell is required to be formed to each of memory cells, and therefore, the area size of the array is increased.

Still further, in a case of configuring the array by arranging a plurality of memory cells in matrix, part of a voltage applied to the selected cell is also applied to the unselected cell, and therefore, such a design is required that a disturb (miss-programming/miss-erasing) which the unselected cell receives is considered. However, there is no detailed description for the design in any of the above-described Patent Documents 1, 2, 3, and 4.

An object of the present invention is to provide a technique in which the scaling down of the area size of the semiconductor chip can be realized in a nonvolatile semiconductor memory device having a split-gate-type memory cell of a MONOS method in particular.

The above and other objects and novel characteristics of the present invention will be apparent from the descriptions of the present specification and the accompanying drawings.

One embodiment of the typical ones of the inventions disclosed in the present application will be briefly described as follows.

The one embodiment is a nonvolatile semiconductor memory device having a nonvolatile memory cell configured with: a control gate; a memory gate; a gate insulator film formed between a semiconductor substrate and the control gate; an insulator for holding a charge having a stacked structure configured with a lower-layer insulator, a charge storing layer, and an upper-layer insulator and formed between the semiconductor substrate and the memory gate and between the control gate and the memory gate; a source diffusion layer; and a drain diffusion layer. Each of the memory gate, the control gate, the source diffusion layer, and the drain diffusion layer is connected to a control circuit for controlling a potential, and the control circuit operates so as to supply a first potential to the memory gate, a second potential to the control gate, a third potential to the drain diffusion layer, and a fourth potential to the source diffusion layer. Here, after setting the memory gate to be in the floating state by the control circuit, the control circuit operates so as to supply a sixth potential higher than the second potential to the control gate to make the memory gate have a fifth potential higher than the first potential, thereby boosting the memory gate.

The effects obtained by one embodiment of typical aspects of the present invention will be briefly described below.

Since the area size of the power supply voltage circuit can be made small in the nonvolatile semiconductor memory device having the split-gate-type memory cell of the MONOS method, the scaling down of the area size of the semiconductor chip can be realized.

### BRIEF DESCRIPTIONS OF THE DRAWINGS

FIG. 1 is a block diagram of a nonvolatile semiconductor memory device according to a first embodiment;

FIG. 2 is a plan view of principal part of a semiconductor substrate showing one example of a memory cell array according to the first embodiment;

FIG. 3 is a cross-sectional view of principal part of the semiconductor substrate taken along the line A-A′ in FIG. 2;

FIG. 4 is a cross-sectional view of principal part of the semiconductor substrate taken along the line B-B′ in FIG. 2;

FIG. 5 is a cross-sectional view of principal part of the semiconductor substrate taken along the line C-C′ in FIG. 2;

FIG. 6 is an equivalent circuit diagram of the memory cell array corresponding to FIG. 2;

FIG. 7 is a schematic plan view describing one example of a connecting region between a memory gate and an adjacent memory gate which are arranged in the memory cell array according to the first embodiment;

FIG. 8 is an equivalent circuit diagram of a switch transistor region formed between the memory gate and a control circuit which are arranged in the memory cell array according to the first embodiment;

FIG. 9 is a cross-sectional view of principal part showing a manufacturing method of the nonvolatile semiconductor memory device according to the first embodiment;

FIG. 10 is a cross-sectional view of principal part of a same part with FIG. 9 in the manufacturing process of the nonvolatile semiconductor memory device continued from FIG. 9;

FIG. 11 is a cross-sectional view of principal part of the same part with FIG. 9 in the manufacturing process of the nonvolatile semiconductor memory device continued from FIG. 10;

FIG. 12 is a cross-sectional view of principal part of the same part with FIG. 9 in the manufacturing process of the nonvolatile semiconductor memory device continued from FIG. 11;

FIG. 13 is a cross-sectional view of principal part of the same part with FIG. 9 in the manufacturing process of the nonvolatile semiconductor memory device continued from FIG. 12;

FIG. 14 is a cross-sectional view of principal part of the same part with FIG. 9 in the manufacturing process of the nonvolatile semiconductor memory device continued from FIG. 13;

FIG. 15 is part of a timing diagram describing a programming operation in the nonvolatile semiconductor memory device according to the first embodiment;

FIG. 16 is a schematic plan view showing one example of a configuration of the memory cell array according to the first embodiment;

FIG. 17 is part of a timing diagram describing a programming operation in a nonvolatile semiconductor memory device according to a second embodiment;

FIG. 18 is part of a timing diagram describing a programming operation in a nonvolatile semiconductor memory device according to a third embodiment;

FIG. 19 is a graph diagram describing a disturb (miss-programming) which an unselected memory cell receives due to the programming operation of a selected memory cell according to the third embodiment;

FIG. 20A is a graph diagram describing a relation between a capacitive coupling ratio of a control gate for a memory gate and a capacitive coupling ratio of a drain diffusion layer or a p-type well for the memory gate;

FIG. 20B is a graph diagram plotting a relation between a boosting potential of the memory gate and the capacitive coupling ratio of the control gate for the memory gate;

FIG. 21 is a graph diagram describing a relation between the capacitive coupling ratio and a film thickness of an insulator film for holding a charge (ONO);

FIG. 22 is an equivalent circuit diagram of a switch transistor region formed between a memory gate and a control gate which are arranged in a memory cell array according to a fourth embodiment;

FIG. 23 is part of a timing diagram describing a programming operation in a nonvolatile semiconductor memory device according to the fourth embodiment;

FIG. 24 is part of a timing diagram describing a programming operation in a nonvolatile semiconductor memory device according to a fifth embodiment;

FIG. 25 is a cross-sectional view of principal part showing a manufacturing method of a nonvolatile semiconductor memory device according to a sixth embodiment;

FIG. 26 is a cross-sectional view of principal part of a same part with FIG. 25 in the manufacturing process of the nonvolatile semiconductor memory device continued from FIG. 25;

FIG. 27 is a cross-sectional view of principal part of the same part with FIG. 25 in the manufacturing process of the nonvolatile semiconductor memory device continued from FIG. 26;

FIG. 28 is a cross-sectional view of principal part of the same part with FIG. 25 in the manufacturing process of the nonvolatile semiconductor memory device continued from FIG. 27;

FIG. 29 is a cross-sectional view of principal part of the same part with FIG. 25 in the manufacturing process of the nonvolatile semiconductor memory device continued from FIG. 28;

FIG. 30 is a cross-sectional view of principal part of the same part with FIG. 25 in the manufacturing process of the nonvolatile semiconductor memory device continued from FIG. 29;

FIG. 31 is part of a timing diagram describing an erasing operation in a nonvolatile semiconductor memory device according to a seventh embodiment;

FIG. 32 is a cross-sectional view of principal part of a semiconductor substrate showing one example of a structure of a switch transistor in a case of using a negative voltage in a memory operation according to an eighth embodiment;

FIG. 33 is a cross-sectional view of principal part of the semiconductor substrate showing one example of the structure of the switch transistor in a case of not using the negative voltage in the memory operation according to the eighth embodiment; and

FIG. 34 is a cross-sectional view of principal part of a semiconductor substrate showing one example of a structure of a twin MONOS memory cell according to a ninth embodiment.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable. Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it can be conceived that they are apparently excluded in principle. The same goes for the numerical value and the range described above.

Still further, in the embodiments described below, a MISFET (Metal Insulator Semiconductor Field Effect Transistor) representing a field-effect transistor is abbreviated as “MIS”, a p-channel type MISFET is abbreviated as “pMIS”, and an n-channel type MISFET is abbreviated as “nMIS”. Still further, in the embodiments described below, when referred to a wafer, the wafer indicates mainly a Si (silicon) single-crystal wafer. However, the wafer indicates not only that but also a SOI (Silicon On Insulator) wafer, an insulator substrate for forming an integrated circuit on itself, and the like. A shape of the wafer is not only a circle shape or almost circle shape but also a square shape, a rectangle shape, and the like.

Moreover, components having the same function are denoted by the same reference symbols throughout the drawings for describing the embodiments, and the repetitive description thereof is omitted. Hereinafter, embodiments of the present invention will be described in detail with reference to the accompanying drawings.

### First Embodiment

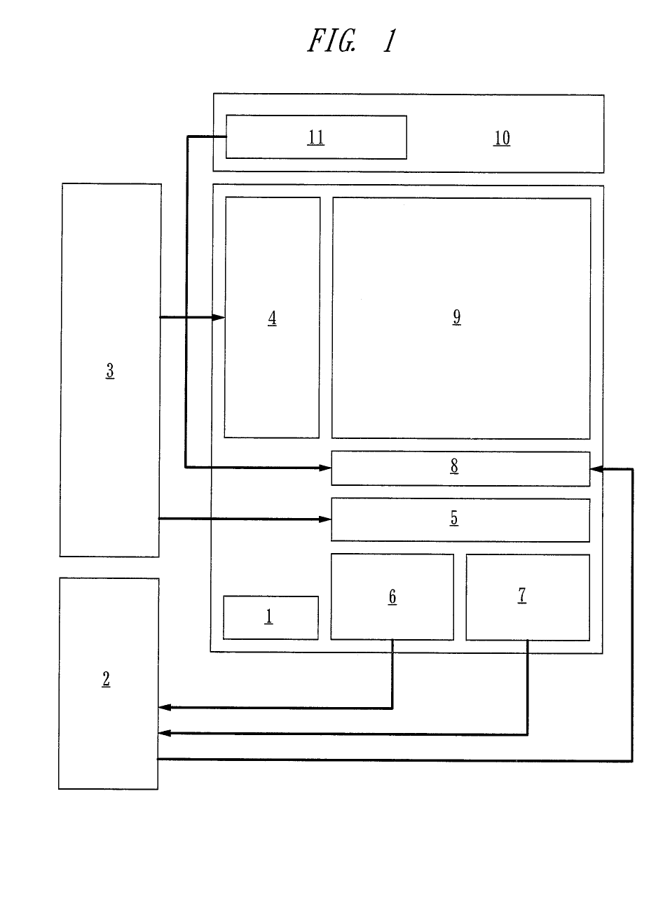

A block diagram of a nonvolatile semiconductor memory device according to a first embodiment is shown in FIG. 1.

The nonvolatile semiconductor memory device according to the first embodiment is configured with: a control circuit 1; an input/output circuit 2; an address buffer 3; a row decoder 4; a column decoder 5; a verify sense amplifier 6; a high-speed read sense amplifier 7; a programming circuit 8; a memory cell array 9; a power supply circuit 10; and others. The control circuit 1 temporary stores a control signal inputted from a host such as a microcomputer of a connection destination of the control circuit to control an operation logic. Also, the control circuit 1 controls a potential of a gate electrode of a memory cell in the memory cell array 9. Each types of data such as data read from the memory cell array 9, data programmed to the memory cell array 9, or program data are inputted and outputted from/to the input/output circuit 2. The address buffer 3 temporary stores an address inputted externally.

The row decoder 4 and the column decoder 5 are connected to the address buffer 3. The row decoder 4 decodes based on a row address outputted from the address buffer 3, and the column decoder 5 decodes based on a column address outputted from the address buffer 3. The verify sense amplifier 6 is a sense amplifier for verifying programming/erasing, and the high-speed read sense amplifier 7 is a sense amplifier for reading which is used in a data reading. The programming circuit 8 latches programming data inputted via the input/output circuit 2 to control the data programming. In the memory cell array 9, a memory cell which is a minimum unit of a memory is orderly arranged in an array position. The power supply circuit 10 is configured with: a voltage generating circuit for generating various voltages used in the data programming/erasing or verifying; a current trimming circuit 11 for generating an any voltage to supply to the programming circuit 8; and others.

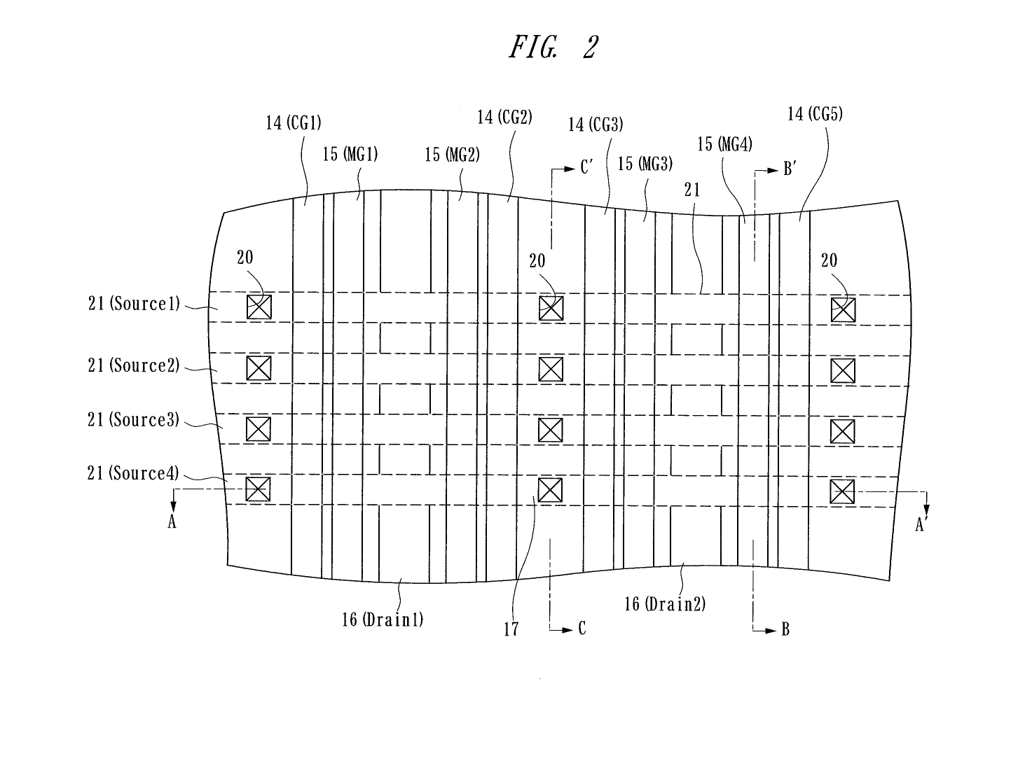

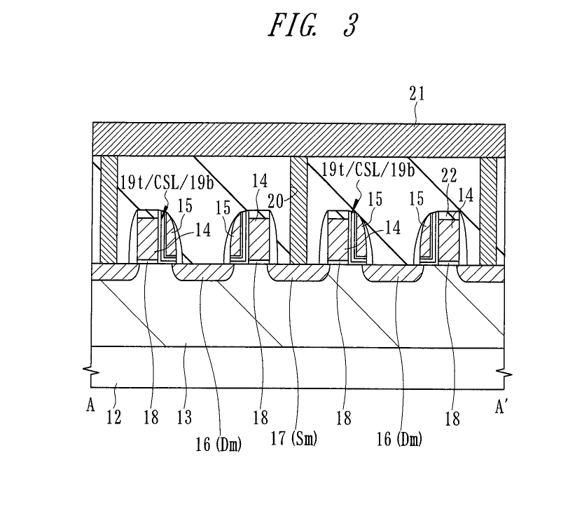

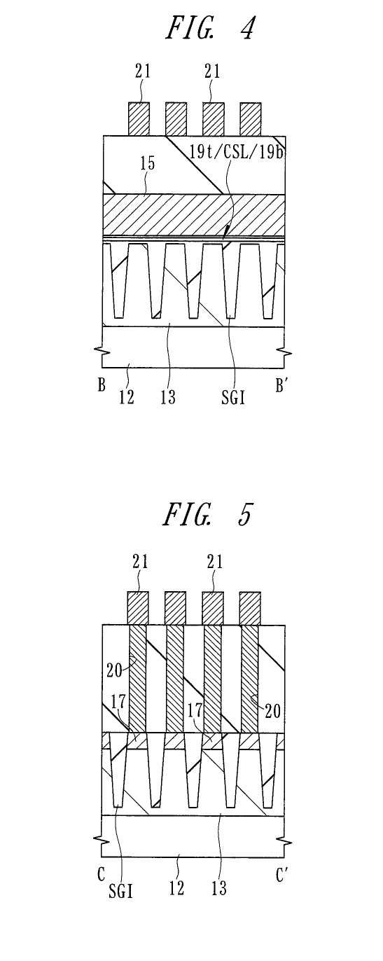

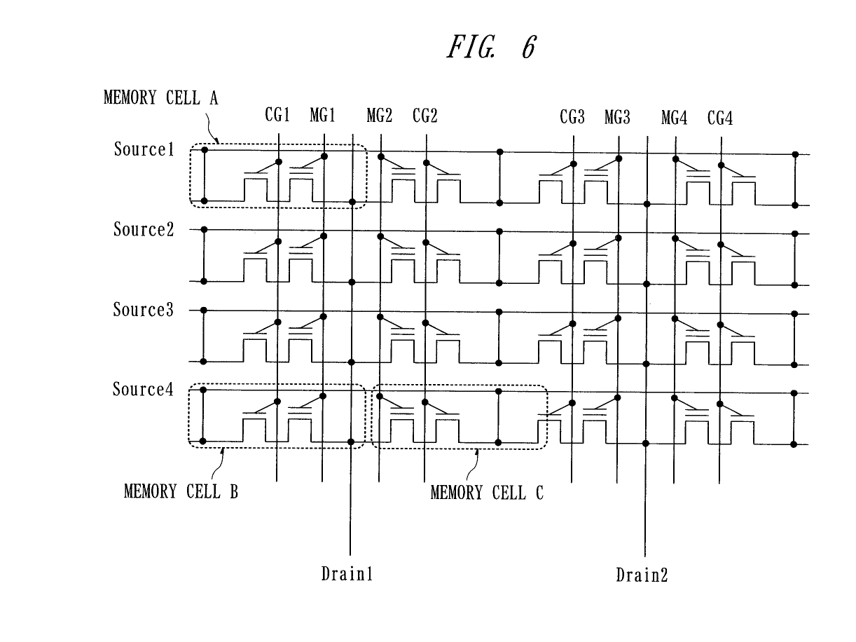

Next, a split-gate-type MONOS memory cell according to the first embodiment will be described with reference to FIG. 2 to FIG. 6. FIG. 2 is a plan view of principal part of a semiconductor substrate showing one example of the memory cell array, FIG. 3 is a cross-sectional view of principal part of the semiconductor substrate along the line A-A′ in FIG. 2, FIG. 4 is a cross-sectional view of principal part of the semiconductor substrate along the line B-B′ in FIG. 2, FIG. 5 is a cross-sectional view of principal part of the semiconductor substrate along the line C-C′ in FIG. 2, and FIG. 6 is an equivalent circuit diagram of the memory cell array corresponding to FIG. 2.

The memory cell (for example, memory cells A, B, and C surrounded by a dotted line shown in FIG. 6) has: a p-type well 13 configured with a p-type semiconductor region formed on a main surface of a semiconductor substrate 12; a control gate 14 of nMIS for a control; and a memory gate 15 of nMIS for a memory, and the control gate 14 and the memory gate 15 are arranged in different regions from each other. An n⁺-type semiconductor region 16 configures a drain diffusion layer Dm of the memory cell, and an n⁺-type semiconductor region 17 configures a source diffusion layer Sm of the memory cell. The control gate 14 of the nMIS for the control and the memory gate 15 of the nMIS for the memory are extended being adjacent to each other between the drain diffusion layer Dm and the source diffusion layer Sm on the main surface of the semiconductor substrate 12, and a plurality of memory cells are adjacent to each other in the extending direction interposing a shallow groove isolation SGI formed in the semiconductor substrate 12.

The control gate 14 of the nMIS for the control and the p-type well 13 are insulated from each other by the gate insulator film 18 formed of, for example, a silicon oxide film. The memory gate 15 of the nMIS for the memory is provided on one side of a sidewall of the control gate 14 of the nMIS for the control, and the control gate 14 of the nMIS for the control and the memory gate 15 of the nMIS for the memory are insulated from each other by an insulator film for holding a charge having a stacked layer of an insulator film 19b, a charge storing layer CSL, and an insulator film 19t (hereinafter, referred to as the insulator films 19b and 19t and the charge storing layer CSL). Also, the memory gate 15 of the nMIS for the memory is arranged on the p-type well 13 via insulator films 19b and 19t and the charge storing layer CSL. Note that “the insulator films 19b and 19t and the charge storing layer CSL” are denoted by “19t/CSL/19b” in FIG. 3 and FIG. 4.

The charge storing layer CSL is provided such that top and bottom thereof is sandwiched by the insulator films 19b and 19t, and the charge storing layer CSL is formed of, for example, a silicon nitride film. The silicon nitride film is an insulator having discrete trap energy levels in the film and having a function of storing charges in the trap energy levels. The insulators 19b and 19t are formed of, for example, a silicon oxide film. The insulators 19b and 19t can be also formed of a silicon oxide film containing nitrogen.

The drain diffusion layer Dm between memory cells which are adjacent to each other is electrically connected to the memory cells via the n⁺-type semiconductor region 16. The source diffusion layer Sm is connected to a metal wiring 21 via a contact hole 20.

The control gate 14 is connected in the row direction to form a word line. The memory gate 15 is connected in the row direction in parallel with the control gate 14. The metal wiring 21 to be a bit line is arranged so as to extend in the column direction at right angle to the word line to configure the memory cell array 9.

Since the control gate 14 and the memory gate 15 are arranged in parallel with each other in the memory cell array 9, a capacitance between the control gate 14 and the memory gate 15 is relatively large so that a capacitive coupling ratio of the control gate 14 for the memory gate 15 is about 0.7. Also, since an overlap between the drain diffusion layer Dm and the memory gate 15 is relatively large, a capacitive coupling ratio of the drain diffusion layer Dm for the memory gate 15 is about 0.15, and a capacitive coupling ratio of the p-type well 13 (channel region) for the memory gate 15 is about 0.1.

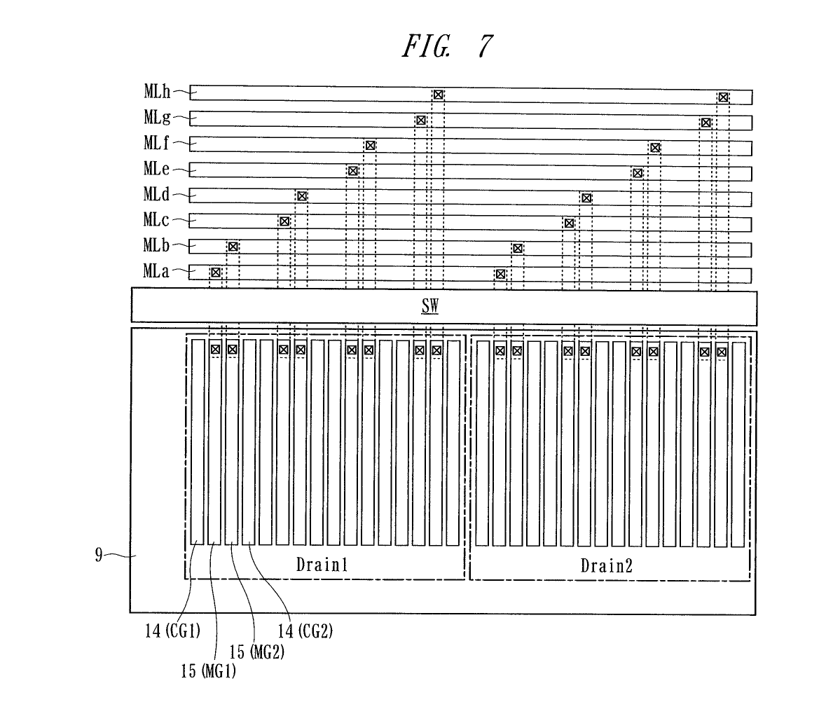

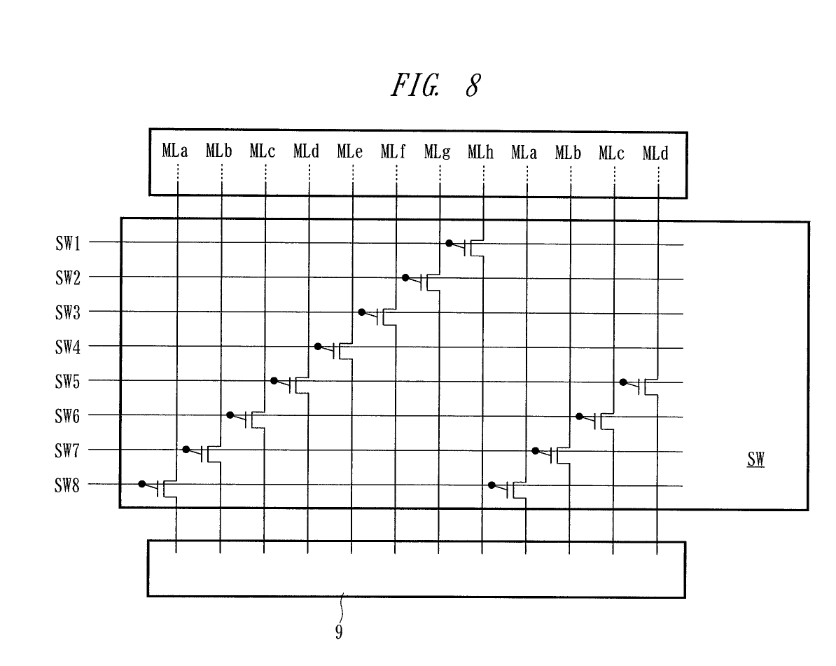

Next, a connecting region between the memory cell array and the control circuit of the nonvolatile semiconductor memory device according to the first embodiment will be described with reference to FIG. 7 and FIG. 8. FIG. 7 is a schematic plan view describing one example of the connecting region between the memory gate and a memory gate adjacent thereto which are arranged in the memory cell array, and FIG. 8 is an equivalent circuit diagram of a switch transistor region formed between the memory gate and the control gate which are arranged in the memory cell array.

As shown in FIG. 7, the control gate 14 and the memory gate 15 described above are orderly arranged in the same direction in the memory cell array 9, and these control gates 14 and the memory gates 15 are common gates to each of the plurality of memory cells. The memory gates 15 are connected to the control circuit, and an array configuration with an eight-line system is shown here. That is, the memory gates 15 are electrically connected to each other at intervals of eight lines by metal wirings MLa, MLb, MLc, MLd, MLe, MLf, MLg, and MLh on the same layer, respectively. Each of these metal wirings MLa, MLb, MLc, MLd, MLe, MLf, MLg, and MLh can individually perform potential control. Also, a switch transistor region SW is provided between the memory cell array 9 and the metal wirings MLa, MLb, MLc, MLd, MLe, MLf, MLg, and MLh, and, for example, the memory gate 15 and the row decoder 4 can be connected and cut off by a switch transistor formed in the switch transistor region SW.

The metal wirings MLa, MLb, MLc, MLd, MLe, MLf, MLg, and MLh are formed by using a metal wiring in a first layer, and a line width/space width is, for example, 0.24 μm/0.24 μm. Of course, the formation is not limited to the metal wiring in the first layer, and the metal wirings MLa, MLb, MLc, MLd, MLe, MLf, MLg, and MLh can be also formed by using a metal wiring in a second or upper layer.

Although not illustrated, the control gates 14 are also connected to the control circuit, and the control gates 14 can individually perform the potential control in each of the lines. Further, the drain diffusion layer Dm and the source diffusion layer Sm are also connected to the control circuit, and each of them can perform the potential control independently. The n⁺-type semiconductor region 16 configuring the drain diffusion layer Dm is divided at intervals of eight lines of the memory gates 15, and each of voltages shown in Table 1 is applied to the region depending on the select/unselect state in the memory operation. Note that, the array configuration is not limited to the eight-line system, and for example, an array configuration of a sixteen-line system can be also used.

TABLE 1

| | MG | CG | Drain | Source | |
|---|---|---|---|---|---|
| | (select) | (select) | (select) | (select) | Well |
| Read | 0 V | 1.5 V | 0 V | 1.5 V | 0 V |
| Program | 10 V | 1 V | 5 V | 0.4 V | 0 V |
| Erase | −6 V | 0 V | 6 V | OPEN | 0 V |

| | MG | | CG | Drain | Source |
|---|---|---|---|---|---|
| | (unselect) | | (unselect) | (unselect) | (unselect) |
| Read | 0 | V | 0 V | 0 V | 0 V |
| Program | 2-2.3 | V | 0 V | 1.5 V | 1.5 V |
| Erase | 1.5 | V | 0 V | 1.5 V | OPEN |

As shown in FIG. 8, the metal wirings MLa, MLb, MLc, MLd, MLe, MLf, MLg, and MLh are connected to the memory gates 15 via switch transistors SW1 to SW8, respectively, so that the memory gates 15 are set to be in the floating state by setting these switch transistors SW1 to SW8 to be in OFF state. Also, the switch transistors SW1 to SW8 are in eight stages.

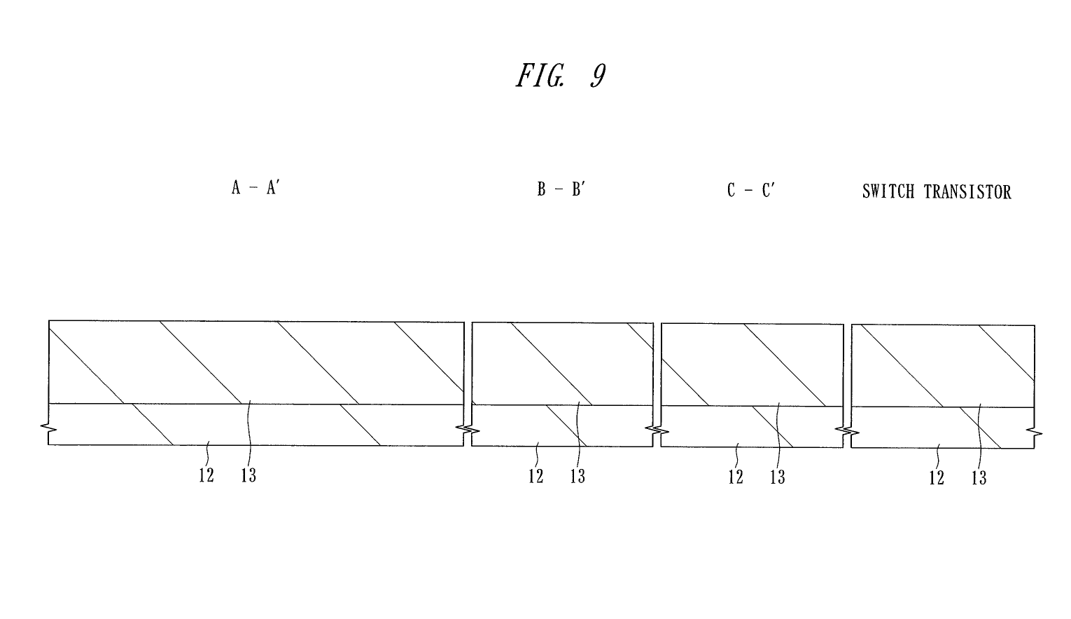

Next, a manufacturing method of the nonvolatile semiconductor memory device according to the first embodiment will be described with reference to FIG. 9 to FIG. 14. FIG. 9 to FIG. 14 show cross-sectional views of principal parts of the split-gate-type MONOS memory cell and the switch transistor, and cross-sectional views of principal parts along the lines A-A′, B-B′, and C-C′ shown in FIG. 2 as described above are shown in the split-gate-type MONOS memory cell.

First, as shown in FIG. 9, there is prepared a semiconductor substrate (at this stage, a semiconductor thin plate with a substantially circle shape in plane which is called a semiconductor wafer) 12 made of a p-type single-crystal silicon having a specific resistance of, for example, about 1 to 10 Ω·cm. Sequentially, a predetermined impurity is selectively injected to a predetermined portion of the semiconductor substrate 12 with a predetermined energy by ion implantation and the like, thereby forming the p-type well 13. Although not illustrated here, a triple well may be formed in, for example, a peripheral circuit region and the like.

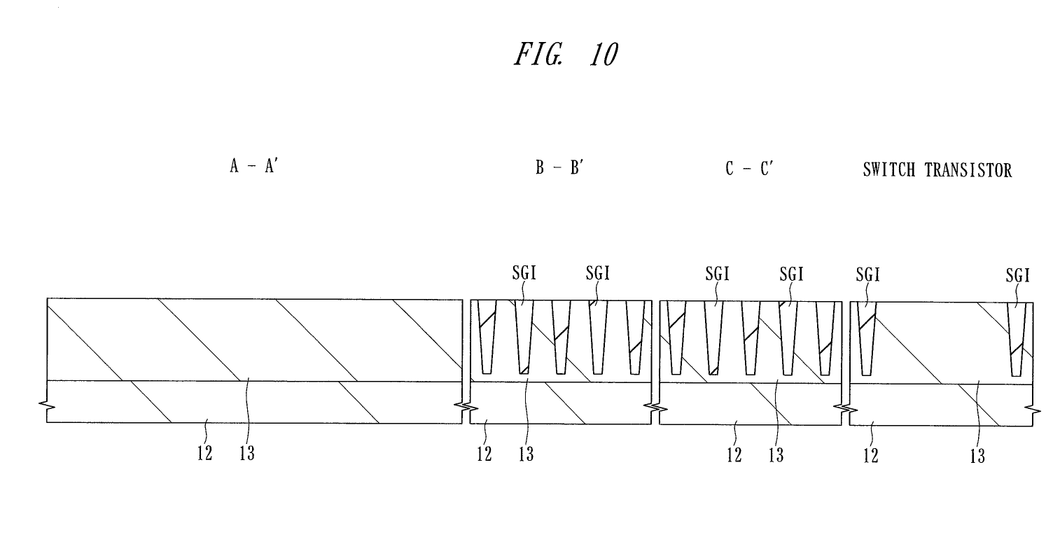

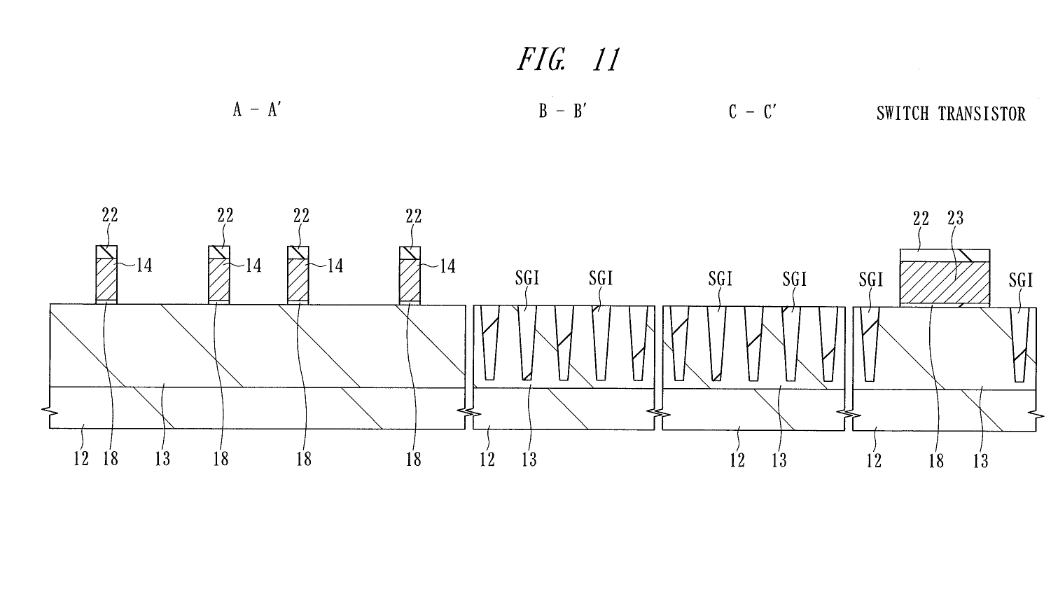

Next, as shown in FIG. 10, for example, a trench-type shallow groove isolation SGI, an active region arranged so as to be surrounded by SGI, and the like are formed on the main surface of the semiconductor substrate 12. That is, after forming an isolation trench on a predetermined portion of the semiconductor substrate 12, an insulator film formed of, for example, a silicon oxide film is deposited on the main surface of the semiconductor substrate 12, and further, the insulator film is polished by CMP (Chemical Mechanical Polishing) method and the like so as to remain the insulator film only inside of the isolation trench, thereby forming the shallow groove isolation SGI.

Next, as shown in FIG. 11, the p-type semiconductor region (an illustration thereof is omitted) for forming the channel of nMIS for the control and the switch transistor are formed by ion implantation of a p-type impurity, for example, boron to the main surface of the semiconductor substrate 12, followed by applying an oxidation process to the semiconductor substrate 12, thereby forming the gate insulator 18, for example, formed of a silicon oxide film and having a thickness of 2.5 nm or less, on the main surface of the semiconductor substrate 12. Subsequently, a first conductive film, for example, formed of a polysilicon film and having an impurity concentration of about 2×10²⁰ cm⁻³ and a silicon oxide film 22 functioning as a hard mask are sequentially deposited on the main surface of the semiconductor substrate 12. The first conductive film is formed by CVD (Chemical Vapor Deposition) method, and its film thickness can be exemplified as, for example, about 150 to 250 nm. Subsequently, after processing the silicon oxide film 22 by using a photo resist pattern as a mask, the first conductive film is processed by using the processed silicon oxide film 22 as a mask, thereby forming the control gate 14 and a gate 23 of the switch transistor. A gate length of the control gate 14 is, for example, about 50 to 200 nm.

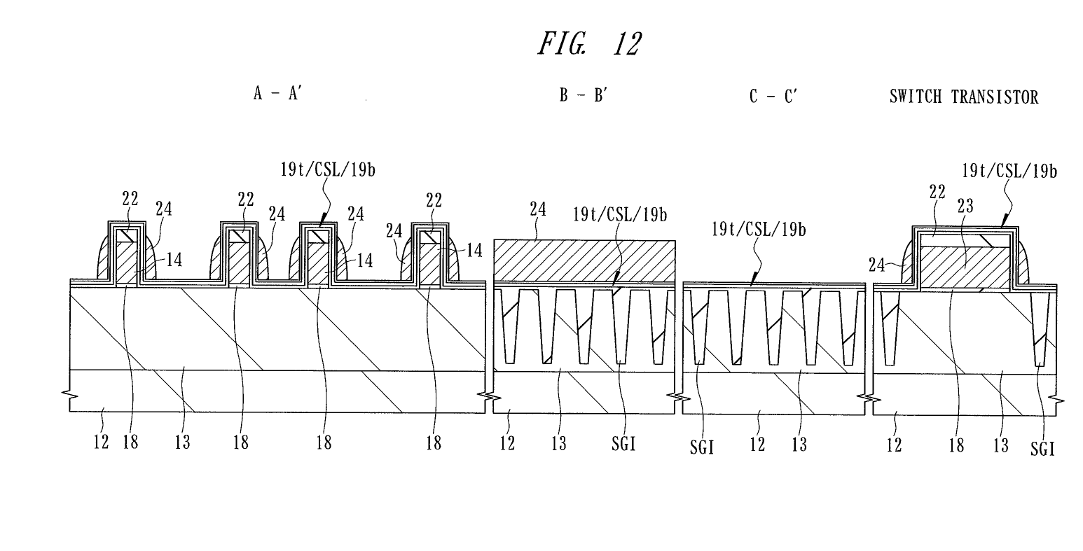

Next, as shown in FIG. 12, the n-type semiconductor region (an illustration thereof is omitted) for forming the channel of nMIS for the memory is formed by ion implantation of an n-type impurity, for example, arsenic or phosphorus to the main surface of the semiconductor substrate 12, and then, for example, the insulator film 19b formed of a silicon oxide film, the charge storing layer CSL formed of a silicon nitride film, and the insulator film 19t formed of a silicon oxide film are sequentially deposited on the main surface of the semiconductor substrate 12. The insulator film 19b is formed by thermal oxidation method and a film thickness of the insulator film 19b can be exemplified as, for example, about 1 to 10 nm. The charge storing layer CSL is formed by CVD method and a film thickness of the charge storing layer CSL can be exemplified as, for example, about 5 to 20 nm. The insulator film 19t is formed by CVD method and a film thickness of the insulator 19t can be exemplified as, for example, about 5 to 15 nm. The insulator films 19b and 19t and the charge storing layer CSL function as the gate insulator of the nMIS for the memory which will be formed later in addition to functioning to hold a charge.

Since a configuration of each film of the insulator films 19b and 19t and the charge storing layer CSL is changed depending on a method of using the manufactured semiconductor device, only typical configurations and values are exemplified here. However, they are not limited to the above-described configurations and values.

Next, a second conductive film, for example, formed of a polysilicon film and having an impurity concentration of about 2×10²⁰ cm⁻³ is deposited on the main surface of the semiconductor substrate 12. The second conductive film is formed by CVD method and its film thickness can be exemplified as, for example, about 30 to 150 nm. Sequentially, an etch-back is performed to the second conductive film by using anisotropic dry-etching method, thereby forming sidewalls 24 on both side surfaces of the control gate 14 and the gate 23 of the switch transistor interposing the insulators 19b and 19t and the charge storing layer CSL. In the step of forming the sidewall 24, the etch-back is performed to the second conductive film with using the insulator film 19t as an etching stopper layer. For not damaging the insulator film 19t and the charge storing layer CSL under the insulator film 19t due to the etch-back, an etching condition with low damage is desired to be set. If the insulator film 19t and the charge storing layer CSL are damaged, a property deterioration of the memory cell such as a deterioration of the charge holding property occurs.

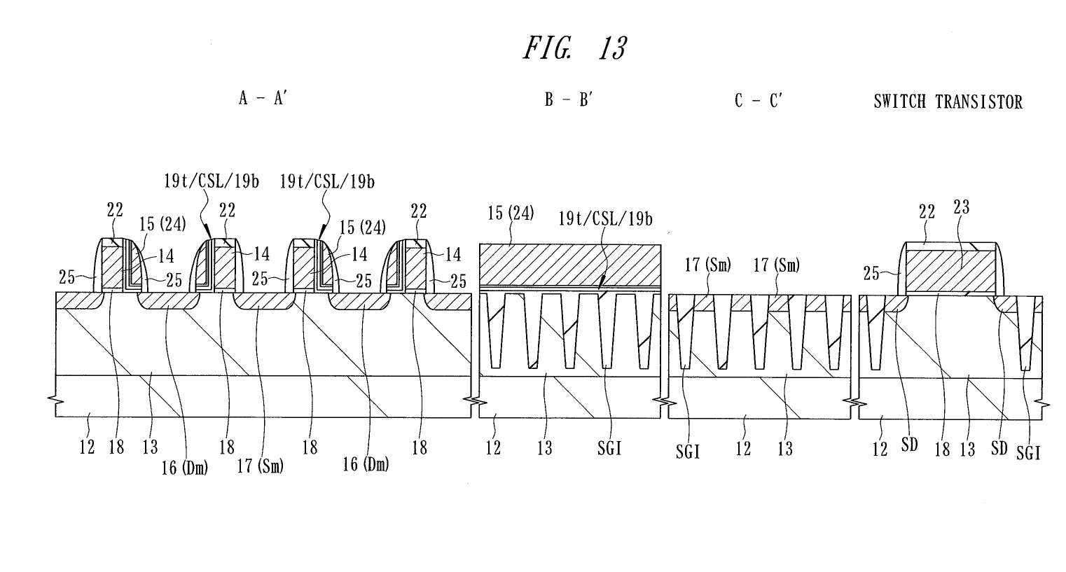

Next, as shown in FIG. 13, a part of the sidewall 24 exposed from a resist pattern is etched by using the resist pattern as a mask, thereby forming the memory gate 15 formed of the sidewall 24 on only one side of the sidewall 24 of the control gate 14. A gate length of the memory gate 15 is, for example, about 50 to 150 nm.

Since the gate length of the memory gate 15 can be determined by the deposition thickness of the second conductive film, the gate length of the memory gate 15 is adjusted by adjusting the deposition thickness of the second conductive film. For example, the gate length of the memory gate 15 can be short when the deposition thickness of the second conductive film is made to be thin, and the gate length of the memory gate 15 can be long when the deposition thickness of the second conductive film is made to be thick.

Next, with remaining the insulators 19b and 19t and the charge storing layer CSL between the control gate 14 and the memory gate 15 and between the semiconductor substrate 12 and the memory gate 15, the insulator films 19b and 19t and the charge storing layer CSL in other region than the remaining part are selectively etched.

Next, after depositing an insulator film formed of, for example, a silicon oxide film and having a thickness of about 80 nm on the main surface of the semiconductor substrate 12 by plasma CVD method, an etch-back is performed to this insulator film by using anisotropic dry-etching method, thereby forming a sidewall 25 on each of one side surface of the control gate 14 and one side surface of the memory gate 15. At the same time, the sidewall 25 is also formed on both side surfaces of the gate 23 of the switch transistor. A spacer length of the sidewall 25 is, for example, about 60 nm. In this manner, the sidewall 25 can cover an exposed side surface of the gate insulator 18 between the control gate 14 and the semiconductor substrate 12 and an exposed side surface of the insulator films 19b and 19t and the charge storing layer CSL between the memory gate 15 and the semiconductor substrate 12.

Next, the n⁺-type semiconductor regions 16 and 17 are formed on the main surface of the semiconductor substrate 12 so that they are self-aligned with the control gate 14 and the memory gate 15 by ion implantation of an n-type impurity, for example, arsenic or phosphorus to the main surface of the semiconductor substrate 12 by using the sidewall 25 as a mask. Thereby, the drain diffusion layer Dm formed of the n⁺-type semiconductor region 16 and the source diffusion layer Sm formed of the n⁺-type semiconductor region 17 are formed. At the same time, a source and drain diffusion layer SD of a switch transistor is formed.

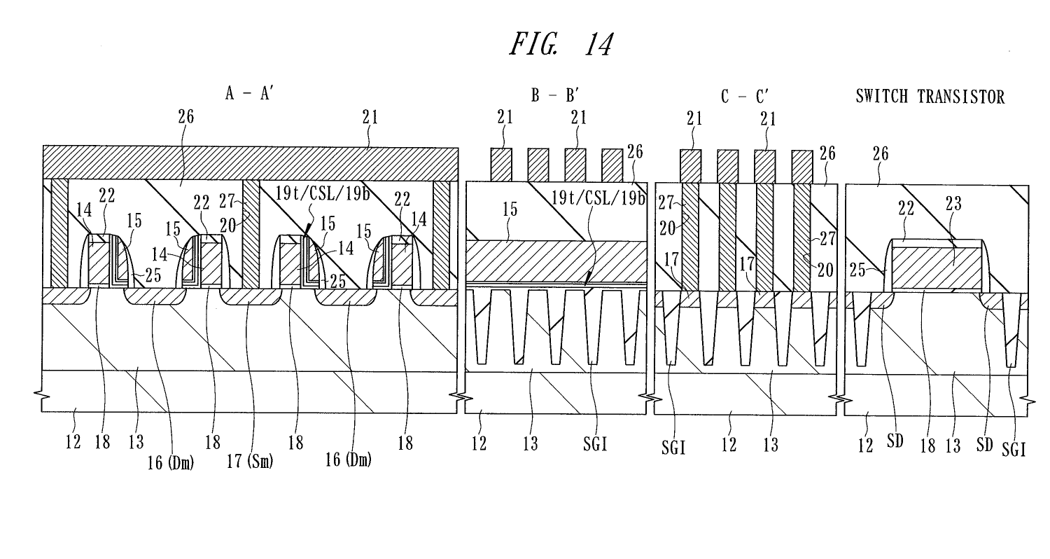

Next, as shown in FIG. 14, an interlayer insulator film 26 formed of, for example, a silicon nitride film and a silicon oxide film is formed on the main surface of the semiconductor substrate 12 by CVD method. Sequentially, after forming a contact hole 20 in the interlayer insulator film 26, a plug 27 is formed inside of the contact hole 20. The plug 27 has, for example, a relatively thin barrier film formed by a stacked film of titanium and titanium nitride and a relatively thick conductive film made of tungsten, aluminum, or the like which is formed so as to be covered by the relatively thin barrier film. And then, a metal wiring 21 in the first layer made of, for example, tungsten, aluminum, cupper, or the like is formed on the interlayer insulator 26, thereby substantially completing the above-described memory cell. After this step, the nonvolatile semiconductor memory device is manufactured through a normal manufacturing process of a semiconductor device.

Next, three operations of (1) a programming operation, (2) an erasing operation, and (3) a reading operation will be described as basic operations of the memory cell according to the first embodiment. Note that, in the first embodiment, an operation of increasing electrons inside of the charge storing layer is defined as the programming operation, and an operation of decreasing electrons is defined as the erasing operation. Also, while the memory cell formed by nMIS is described in the first embodiment for an explanation, a memory cell formed by pMIS can be similarly considered in principle.

(1) In the programming operation, a positive potential (for example, 5 V) is applied to the drain diffusion layer Dm so that the p-type well 13 is grounded. By applying a high gate overdrive voltage (for example, 10 V) to the memory gate 15, the channel region under the memory gate 15 is set to the ON state. Here, by setting a potential of the control gate 14 to be a voltage which is, for example, about 0.1 V to 0.2 V higher than a threshold voltage, the channel region under the control gate 14 is set to the ON state. Next, a potential causing a desired channel current flow (for example, 0.4 V) is applied to the source diffusion layer Sm. In this voltage condition, a strong electric field is generated in the channel region under and between the memory gate 15 and the control gate 14, thereby generating a lot of hot electrons. The programming is performed by injecting part of the generated hot electrons to the memory gate 15 side. Generally, this phenomenon is called “Source Side Injection (SSI)”.

(2) In the erasing operation, a negative potential (for example, −6 V) is applied to the memory gate 15, and a positive potential (for example, 6 V) is applied to the drain diffusion layer Dm. In this manner, band-to-band tunnel phenomenon occurs by generating strong inversion in an overlapped region between an end portion of the drain diffusion layer Dm and the memory gate 15 so that holes can be formed. The generated holes are accelerated towards the channel region direction and are pulled by the potential of the memory gate 15 so that they are injected to the inside of the charge storing layer CSL, thereby performing the erasing operation.

(3) In the reading operation, a positive potential (for example, 1.5 V) is applied to the source diffusion layer Sm in the programming/erasing so that the drain diffusion layer Dm in the programming/erasing is grounded. By applying a positive voltage (for example, 1.5 V) to the control gate 14, the channel region under the control gate 14 is set to the ON state. With this state, by applying a proper voltage (for example, 0 V) capable of determining a threshold voltage difference of the memory gate 15 in the programming/erasing to the memory gate 15, a current can be set to flow in the channel region under the memory gate 15 in the erasing state, and a current can be set almost not to flow in the channel region under the memory gate 15 in the programming state. Therefore, the programming/erasing states of the memory cell can be determined by an amount of the current flow in the channel region under the memory gate 15.

Here, in the unselected memory cell which is not a target of the programming operation, the erasing operation, and the reading operation, a miss operation of the memory is suppressed by producing the power supply voltage as shown in Table 1 and applying the voltage to the unselected memory cell in each of (1) the programming operation, (2) the erasing operation, and (3) the reading operation. More particularly, the voltage applied to the memory gate 15 of the unselected memory cell is set to be a proper voltage condition not causing the miss operation of the memory cell in the programming/erasing because of reasons such that electrons injected to the charge storing layer move to the memory gate 15, electrons are injected from the semiconductor substrate to the charge storing layer, and the holes are injected from the memory gate 15 to the charge storing layer.

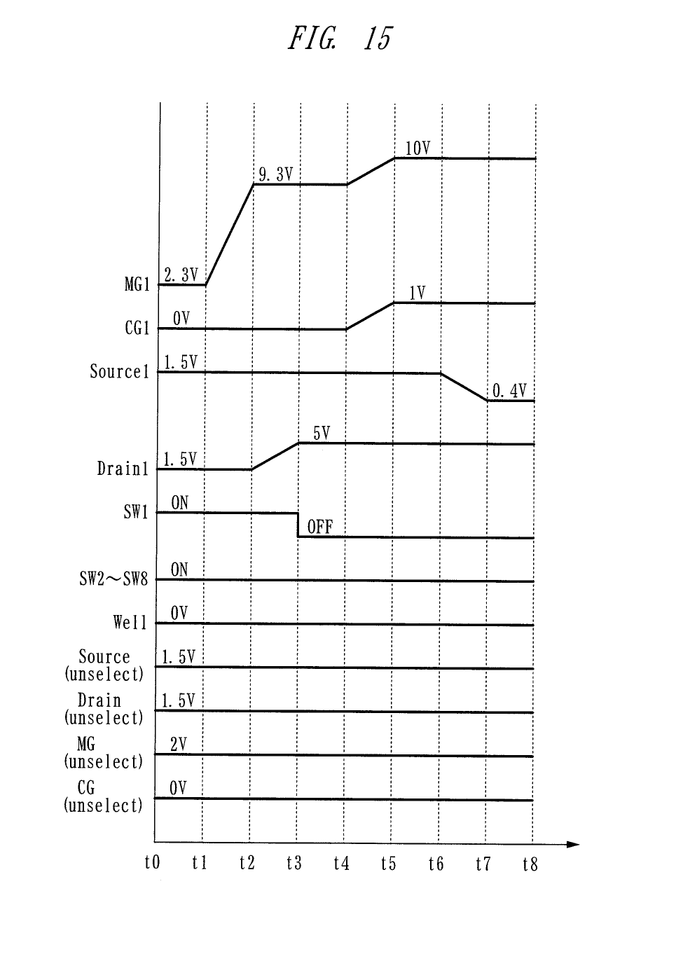

Next, part of a timing diagram describing the programming operation in the nonvolatile semiconductor memory device according to the first embodiment is shown in FIG. 15. Here, a case of selecting the memory cell A shown in the above-described FIG. 6 will be described as one example. The switch transistor for setting the memory gate to be in the floating state is the switch transistor SW1 shown in the above-described FIG. 8. Further, in the first embodiment, the potential supply to the memory gate and the control gate and the ON/OFF operation of each of switch transistors are performed by the operation of the control circuit 1 shown in the above-described FIG. 1, unless otherwise stated.

First, at time to, voltages of an unselected memory cell (unselect) shown in the above-described Table 1 are applied to a selected memory gate (MG1), a selected control gate (CG1), a selected drain diffusion layer (Drain1), and a selected source diffusion layer (Source1) in the selected memory cell A. Here, the switch transistors SW1 to SW8 are in the ON state for supplying a voltage to each of the memory gates.

Next, at time t1, a voltage applied to the selected memory gate (MG1) is started to be increased, and the voltage becomes 9.3 V at time t2.

At the same time of time t2, a voltage applied to the selected drain diffusion layer (Drain1) is started to be increased, and the voltage becomes 5 V at time t3. At time t3, the switch transistor SW1 is set to be in the OFF state to set the selected memory gate (MG1) to be in the floating state.

From time t4 to time t5, the voltage applied to the selected control gate (CG1) is increased from 0 V to 1 V. At this time, the potential of the selected memory gate (MG1) is boosted from 9.3 V to 10 V by the capacitive coupling between the selected control gate (CG1) and itself. Here, the selected control gate (CG1) becomes the OFF state because the voltage applied to the selected source diffusion layer (Source1) is higher than the voltage applied to the selected control gate (CG1) in this state, and therefore, a current does not flow to the channel region.

From time t6, the voltage applied to the selected source diffusion layer (Source1) is started to be decreased, and the voltage is set to be desirably 0.4 V at time t7. In this state, the programming operation is started by a current flow to the channel region.

In this manner, according to the above-described programming sequence in the first embodiment, since the potential of the selected memory gate (MG1) can be boosted by the capacitive coupling between the selected control gate (CG1) and itself, the voltage applied to the selected memory gate (MG1) in the programming can be smaller as much as the boosted amount, thereby capable of scaling down the area size of the power supply voltage circuit. Note that, although details will be described later in a third embodiment, the capacitive coupling ratio of the selected control gate (CG1) for the selected memory gate (MG1) can be increased more in the boosting potential by, for example, making thicker in the thickness of the first conductive film (for example, a polysilicon film) configuring the selected control gate (CG1).

Also, in the first embodiment, since the gate 23 of the switch transistor SW1 is formed of the first conductive film (for example, a polysilicon film) on a same layer with the control gate 14, the number of steps of the manufacturing process does not increase.

Further, in the first embodiment, since the part of the memory cell between the memory gate 15 and the control gate 14 is insulated by the insulator films 19b and 19t and the charge storing layer CSL, there are the following effects.

1. Since the charge storing layer CSL includes a silicon nitride film having a higher dielectric constant than that of a silicon oxide film, its capacitive coupling ratio can be improved.

2. Since the gate insulator film of the nMIS for the memory is formed on the same layer and at the same time with the insulator films 19b and 19t and the charge storing layer CSL which are formed between the memory gate 15 and the control gate 14, a variation in the capacitive coupling ratio due to a variation in the process is small (a detail thereof will be described below in the third embodiment), so that a variation of the boosting potential can be reduced, thereby capable of suppressing a variation of the programming.

3. Since a dielectric breakdown voltage becomes high, this manner is preferable for a case of applying a higher voltage to the memory gate 15.

4. Further, since the insulator film between the boosting control gate 14 and the boosted memory gate 15 is formed by the deposition of using, for example, CVD method, a distance between the control gate and the memory gate can be shortened by thinning the insulator film between both gates compared to, for example, the above-described Patent Document 1 (adjacent word lines formed by lithography technique and etching technique), thereby capable of improving the capacitive coupling between the gates.

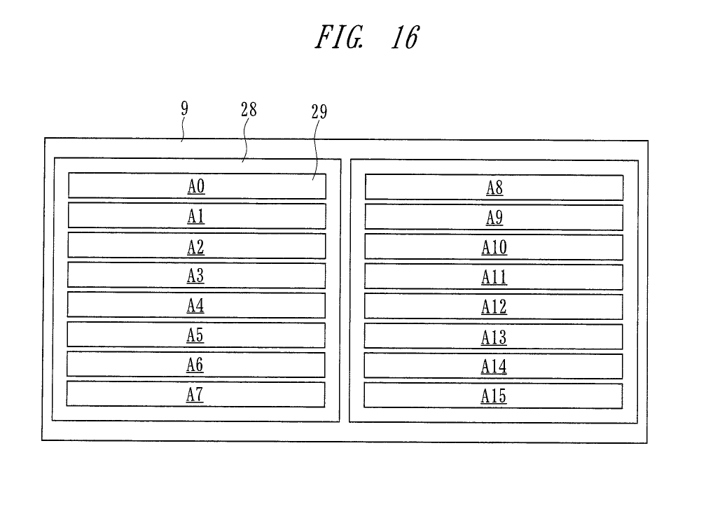

Note that, although the example of the selected memory gate (MG1) of the one-line system is shown in the first embodiment, in a case of configuring the memory cell array 9 with a plurality of memory mats 28 or a plurality of memory blocks 29 (A0 to A15) as shown in FIG. 16, a memory gate having a plurality of lines of the system is selected in each of the plurality of memory mats 28 or each of the plurality of memory blocks 29 (A0 to A15) to boost a potential at the same time, so that the programming operations are performed in parallel. It is needless to say that target cells to perform the programming operations in parallel may be memory cells existing in a same block or may be memory cells existing in different blocks.

Also, the applied voltage shown in the above-described Table 1 is adopted for convenience in the first embodiment. However, the boosting effect of the potential by the capacitive coupling is expressed by the following.

(the capacitive coupling ratio)×(the potential variation of the adjacent gate)

Therefore, it is needless to say that the effect can be increased by, for example, performing the programming with setting the voltage applied to the control gate to 1 V or more, increasing the voltage from 0 V or less, or the like.

### Second Embodiment

A nonvolatile semiconductor memory device according to a second embodiment has the split-gate-type MONOS memory cell as the memory cell similar to the above-described first embodiment. However, how to boost is different from the above-described first embodiment. That is, while the potential of the memory gate is boosted by using the control gate in the above-described first embodiment, the potential of the memory gate is boosted by using the drain diffusion layer in the second embodiment. Therefore, the manufacturing method, the circuit configuration of the switch transistor region, and others are same with those of the above-described first embodiment.

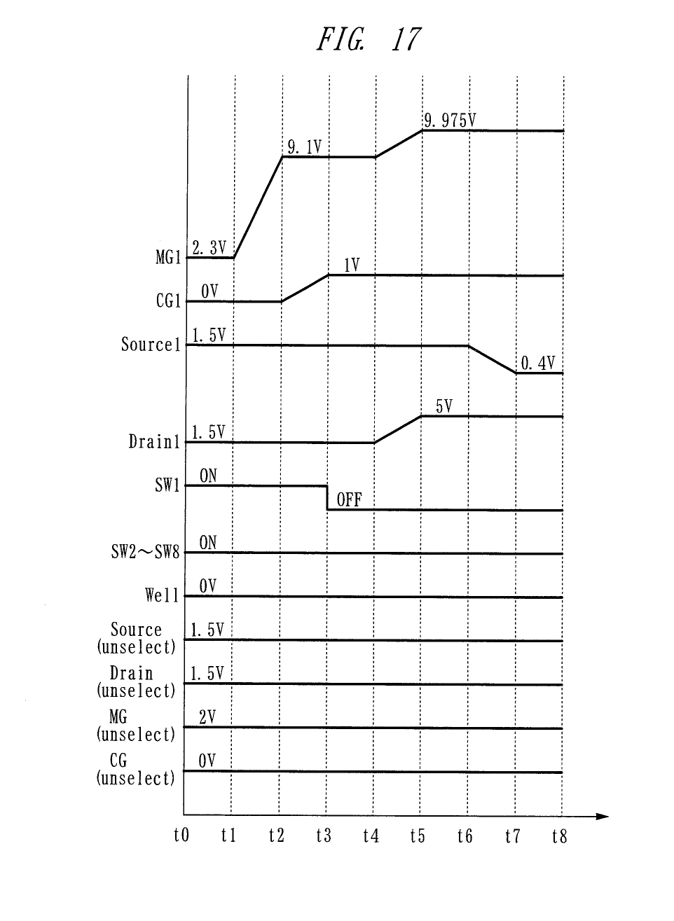

A part of a timing diagram describing a programming operation in the nonvolatile semiconductor memory device according to the second embodiment is shown in FIG. 17. Here, similar to the above-described first embodiment, the case of selecting the memory cell A shown in the above-described FIG. 6 will be described as one example. The switch transistor setting the memory gate to be in the floating state is the switch transistor SW1 shown in the above-described FIG. 8. Further, in the second embodiment, the potential supply to the memory gate and the control gate and the ON/OFF operation of each of switch transistors are performed by the operation of the control circuit 1 shown in the above-described FIG. 1, unless otherwise stated.

First, at time t0, voltages of an unselected memory cell (unselect) shown in the above-described Table 1 are applied to a selected memory gate (MG1), a selected control gate (CG1), a selected drain diffusion layer (Drain1), and a selected source diffusion layer (Source1) in the selected memory cell A. Here, the switch transistors SW1 to SW8 are in the ON state for supplying a voltage to each of the memory gates.

Next, at time t1, a voltage applied to the selected memory gate (MG1) is started to be increased, and the voltage becomes 9.1 V at time t2.

At the same time of time t2, a voltage applied to the selected control gate (CG1) is started to be increased, and the voltage becomes 1 V at time t3. At time t3, the switch transistor SW1 is set to be in the OFF state so that the selected memory gate (MG1) becomes the floating state.

From time t4 to time t5, a voltage applied to the selected drain diffusion layer (Drain1) is increased from 1.5 V to 5 V. At this time, the strong inversion is generated in the selected memory gate (MG1) so that the voltage applied to the selected drain diffusion layer (Drain1) reaches the channel region, and therefore, the capacitive coupling between the selected drain diffusion layer (Drain1) and the channel region (well) occurs, thereby boosting the potential of the selected memory gate (MG1) from 9.1 V to substantially 10 V. Also, the selected control gate (CG1) becomes the OFF state because the voltage applied to the selected source diffusion layer (Source1) is higher than the voltage applied to the selected control gate (CG1) in this state, and therefore, a current does not flow to the channel region.

From time t6, the voltage applied to the selected source diffusion layer (Source1) is started to be decreased, and the voltage is set to be desirably 0.4 V at time t7. In this state, the programming operation is started by a current flow to the channel region.

In this manner, according to the second embodiment, the same effects with the above-described first embodiment can be obtained.

Also, although details will be described later in the third embodiment, the capacitive coupling ratio of the selected control gate (CG1) for the selected memory gate (MG1) is made to be smaller by, for example, reducing the thickness of the first conductive film (for example, a polysilicon film) configuring the selected control gate (CG1), so that the boosted potential can relatively increase the capacitive coupling ratio between the selected drain diffusion layer (Drain1) and the well.

Further, in the above-described first embodiment, since the gate insulator film 18 of the nMIS for the control has an extremely thin thickness of 2.5 nm or less, the voltage applied to the control gate 14 is limited by a dielectric breakdown voltage between the p-type well 13 and the control gate 14. However, in the second embodiment, since the potential of the memory gate 15 is boosted by the n⁺-type semiconductor region 16 configuring the drain diffusion layer Dm, the dielectric breakdown voltage is limited by the gate insulator film of the nMIS for the memory which is thicker than the gate insulator film 18 of the nMIS for the control, that is the insulator film for holding charges (the insulator films 19b and 19t and the charge storing layer CSL), thereby capable of boosting to a higher potential. Moreover, in the second embodiment, the potential of the memory gate can be boosted by using the drain diffusion layer of the memory cell. Therefore, compared to the above-described Patent Documents 3 and 4 (a diffusion layer for boosting a word line differing from a source and a drain diffusion layers of a memory cell is formed in each of memory cells), the area size can be small in addition to a simplification of the manufacturing process.

### Third Embodiment

A nonvolatile semiconductor memory device according to a third embodiment has the split-gate-type MONOS memory cell as the memory cell similar to the above-described first embodiment. However, how to boost is different from the above-described first embodiment. That is, while the potential of the memory gate is boosted by using the control gate in the above-described first embodiment, the potential of the memory gate is boosted by combining the control gate and the drain diffusion layer to perform the programming operation in the third embodiment. Therefore, the manufacturing method, the circuit configuration of the switch transistor region, and others are same with those of the above-described first embodiment.

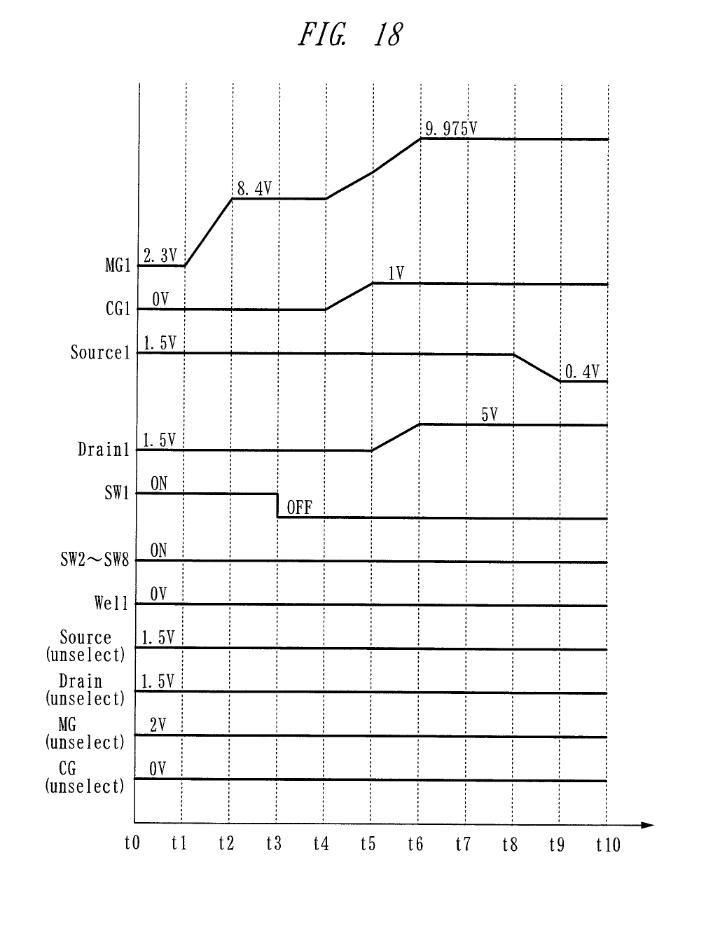

A part of a timing diagram describing a programming operation in the nonvolatile semiconductor memory device according to the third embodiment is shown in FIG. 18. Here, similar to the above-described first embodiment, a case of selecting the memory cell A shown in the above-described FIG. 6 will be described as one example. The switch transistor setting the memory gate to be in the floating state is the switch transistor SW1 shown in the above-described FIG. 8. Further, in the third embodiment, the potential supply to the memory gate and the control gate and the ON/OFF operation of each of switch transistors are performed by the operation of the control circuit 1 shown in the above-described FIG. 1, unless otherwise stated.

First, at time t0, a voltage of an unselected memory cell (unselect) shown in the above-described Table 1 is applied to a selected memory gate (MG1), a selected control gate (CG1), a selected drain diffusion layer (Drain1), and a selected source diffusion layer (Source1) in the selected memory cell A. Here, the switch transistors SW1 to SW8 are in the ON state for supplying a voltage to each of memory gates.

Next, at time t1, a voltage applied to the selected memory gate (MG1) is started to be increased, and the voltage becomes 8.4 V at time t2.

At time t3, the switch transistor SW1 is set to be in the OFF state so that the selected memory gate (MG1) becomes the floating state. From time t4 to time t5, a voltage applied to the selected control gate (CG1) is increased from 0 V to 1 V. From time t5 to time t6, a voltage applied to the selected drain diffusion layer (Drain1) is increased from 1.5 V to 5 V. At this time, the potential of the selected memory gate (MG1) is boosted from 8.4 V to substantially 10 V by the capacitive coupling between the selected drain diffusion layer (Drain1) and itself. Here, the selected control gate (CG1) becomes the OFF state because the voltage applied to the selected source diffusion layer (Source1) is higher than the voltage applied to the selected control gate (CG1) in this state, and therefore, a current does not flow to the channel region.

From time t8, the voltage applied to the selected source diffusion layer (Source1) is started to be decreased, and the voltage is set to be desirably 0.4 V at time t9. In this state, the programming operation is started by a current flow to the channel region.

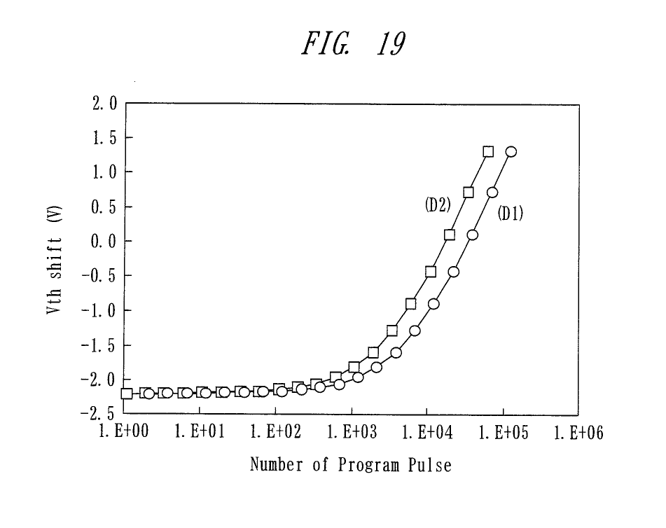

FIG. 19 shows a graph diagram describing a disturb (miss-programming) which the unselected memory cell receives due to the programming operation to the selected memory cell. A vertical axis of FIG. 19 indicates a shift amount of a threshold voltage (Vth) of the unselected memory cell, and a horizontal axis of FIG. 19 indicates the number of programming pulses (1 pulse: 4.6 μs), and FIG. 19 shows a disturb characteristic of the unselected memory cell in a case of changing an order of voltages applied to the selected control gate or the selected drain diffusion layer. In FIG. 19, (D1) is a disturb characteristic in a case of increasing the voltages in an order from the selected control gate→the selected drain diffusion layer, and (D2) is a disturb characteristic in a case of increasing the voltages in an order from the selected drain diffusion layer→the selected control gate. Note that the considering disturb is a disturb caused in the unselected memory cell B in the above-described FIG. 6, and FIG. 19 shows a disturb which the unselected memory cell B receives for a total number of applying pulses in a case of programming information to all of memory cells connected to the selected memory gate.

A same voltage with the selected memory cell A is applied to the memory gate, the control gate, and the drain diffusion layer in the unselected memory cell B, and a voltage of 1.5 V is applied to the source diffusion layer in the unselected memory cell B, thereby preventing the programming.

As shown in FIG. 19, the disturb characteristic in the case of applying the voltage to the selected drain diffusion layer for a long time (D2) is worse than that in the case of applying the voltage to the control gate for a long time (D1). The reason of this is considered such that, since the voltage applied to the drain diffusion layer in the unselected memory cell B is 5 V as a high voltage and the voltage applied to the control gate is lower than the voltage applied to the drain diffusion layer, hot electrons occurs in the channel region under the insulator film between the memory gate and the control gate, and the hot electrons are injected to the charge storing layer, thereby causing the miss-programming to the unselected memory cell B. Therefore, as the order of the voltages applied to the selected control gate or the selected drain diffusion layer in the selected memory cell A, it is desired to increase the voltage of the selected control gate first followed by increasing the voltage of the selected drain diffusion layer, thereby capable of preventing the disturb in the unselected memory cell B.

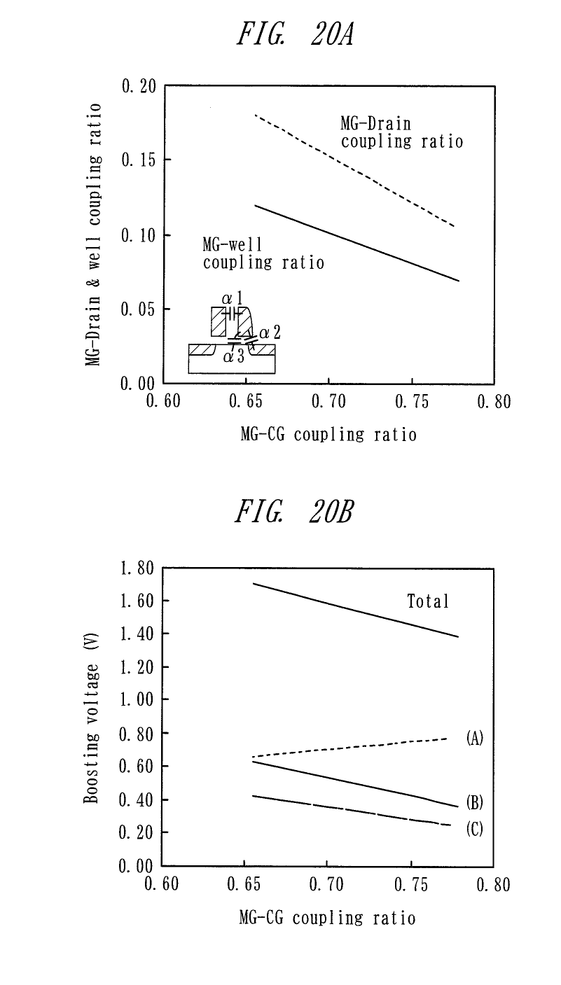

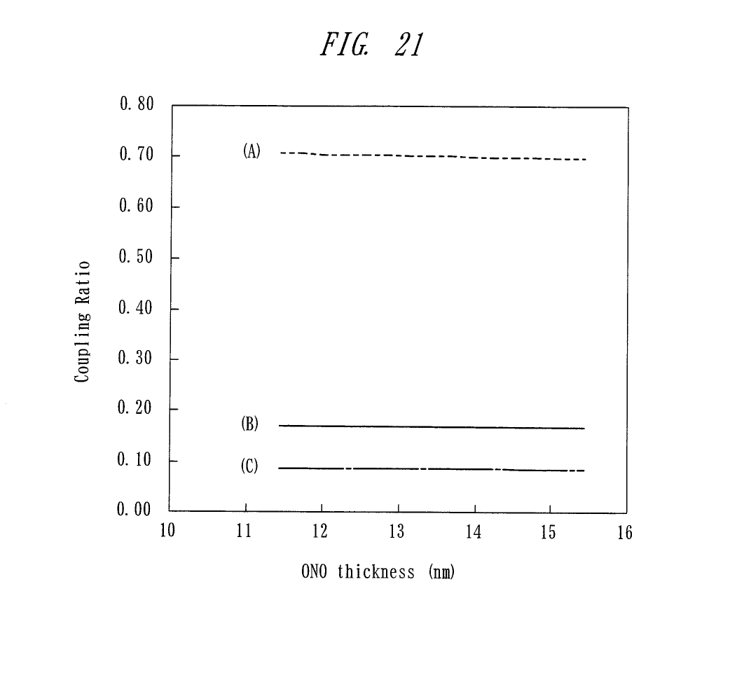

FIG. 20A shows a graph diagram describing a relation between a capacitive coupling ratio of the control gate for the memory gate (α1 of an inserted diagram) and a capacitive coupling ratio of the drain diffusion layer for the memory gate (α2 of the inserted diagram) or a capacitive coupling ratio of the p-type well for the memory gate (α3 of the inserted diagram) in a case of changing a deposition thickness of the first conductive film (for example, a polysilicon film) configuring the control gate to change the capacitive coupling ratio of the control gate for the memory gate. Also, FIG. 20B shows, based on the relations of the capacitive couplings shown in FIG. 20A and the voltage conditions shown in the above-described Table 1, a graph diagram plotting a relation between a boosting potential of the memory gate and the capacitive coupling ratio of the control gate for the memory gate. The line (A) in FIG. 20B indicates the boosting potential of the memory gate according to the capacitive coupling ratio between the memory gate and the control gate, the line (B) indicates the boosting potential of the memory gate according to the capacitive coupling ratio between the memory gate and the drain diffusion layer, and the line (C) indicates the boosting potential of the memory gate according to the capacitive coupling ratio between the memory gate and the p-type well.

As shown in FIG. 20A and FIG. 20B, when the capacitive coupling ratio between the memory gate and the control gate is made smaller, the capacitive coupling ratio between the memory gate and the drain diffusion layer and the capacitive coupling ratio between the memory gate and the p-type well become relatively larger. Accordingly, in a case of boosting the memory gate by using the capacitive coupling ratio of the control gate, the drain diffusion layer, and the p-type well for the memory gate, it is considered that, the capacitive coupling ratio between the memory gate and the control gate is made smaller so that the capacitive coupling ratio between the memory gate and the drain diffusion layer and the capacitive coupling ratio between the memory gate and the p-type well become relatively larger, thereby capable of increasing the boosting effect.

FIG. 21 shows a graph diagram describing a relation between the capacitive coupling ratio and the film thickness of the insulator film for holding charges (for example, the insulator films 19b and 19t and the charge storing layer CSL shown in the above-described FIG. 3). In FIG. 21, the line (A) indicates the capacitive coupling ratio between the memory gate and the control gate, the line (B) indicates the capacitive coupling ratio between the memory gate and the drain diffusion layer, and the line (C) indicates the capacitive coupling ratio between the memory gate and the p-type well.

As shown in FIG. 21, since the insulator film for holding charges between the memory gate and the control gate and the insulator film for holding charges between the memory gate and the p-type well are formed on the same layer and at the same time, a variation of the capacitive coupling ratio is small for the film thicknesses of the insulator films for holding charges.

In this manner, also in the third embodiment, the same effect with the above-described first embodiment can be obtained. Since the boosting potentials are summed by boosting the memory gate in combination of the control gate and the drain diffusion layer, the power supply voltage can be reduced compared to the above-described first embodiment, thereby capable of further scaling down the area size of the power supply voltage circuit.

Also, the variations of the capacitive coupling ratios are small so that variations of the boosting potentials of the memory gate can be reduced, thereby capable of suppressing the variation of the programming.

Note that, although the timing diagram in which the voltage of the control gate is increased first in order to decrease the disturb of the programming-unselected memory cell is shown in the third embodiment, it is needless to say that the voltage of the drain diffusion layer may be increased first. As described later in a fifth embodiment, the boosting voltage of the memory gate is increased by increasing the potential of the drain diffusion layer from a potential lower than that of the source diffusion layer, thereby capable of decreasing the voltage applied to the memory gate. Thereby, the scaling down of the area size of the power supply circuit can be achieved.

Also, although not illustrated, it becomes possible to apply the desired voltage shown in Table 1 to the unselected memory gate by setting the memory gate in the selected memory cell and the memory gate in the unselected memory cell to be in the floating state at the same time and increasing the voltage applied to the selected control gate and the selected drain diffusion layer. In this manner, the voltage applied to the unselected memory gate can be provided by using only an existing power supply voltage, thereby capable of scaling down the area size of the power supply circuit. A fourth embodiment described below in which a configuration of the switch transistor is a one-stage configuration will be described similarly with reference to a timing diagram.

### Fourth Embodiment

A nonvolatile semiconductor memory device according to a fourth embodiment performs the programming operation by boosting the voltage of the memory gate in combination of the control gate and the drain diffusion layer similar to the above-described third embodiment. However, the configuration (the number of stages) of the switch transistors is different from the above-described third embodiment. That is, while the eight-stage configuration (for example, refer to the switch transistor region shown in the above-described FIG. 8) is adopted in the above-described third embodiment, a one-stage configuration is adopted in the fourth embodiment. Note that, a connecting region and a manufacturing method of a control circuit and a memory gate arranged in a memory cell array according to the fourth embodiment are same with those of the control circuit and the memory gate arranged in the memory cell array described in the above-described first embodiment (for example, refer to the plan view shown in the above-described FIG. 7).

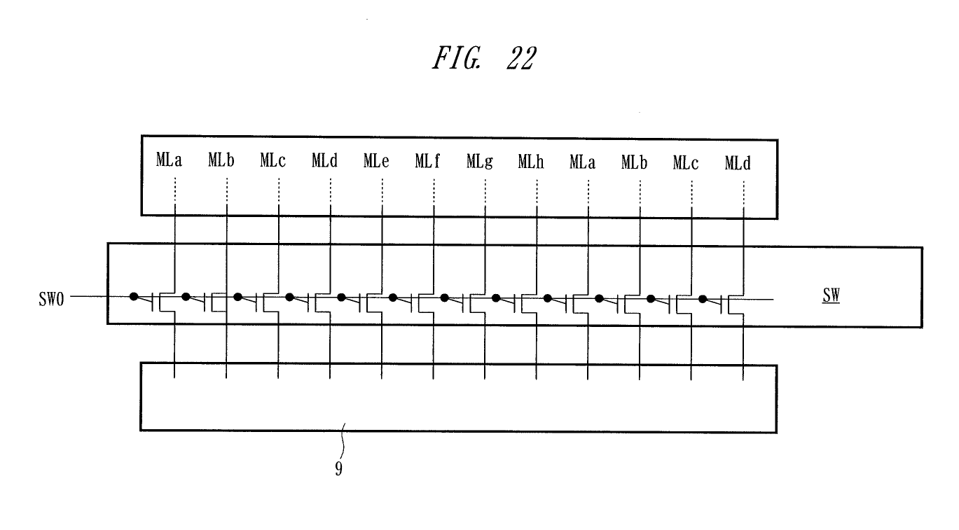

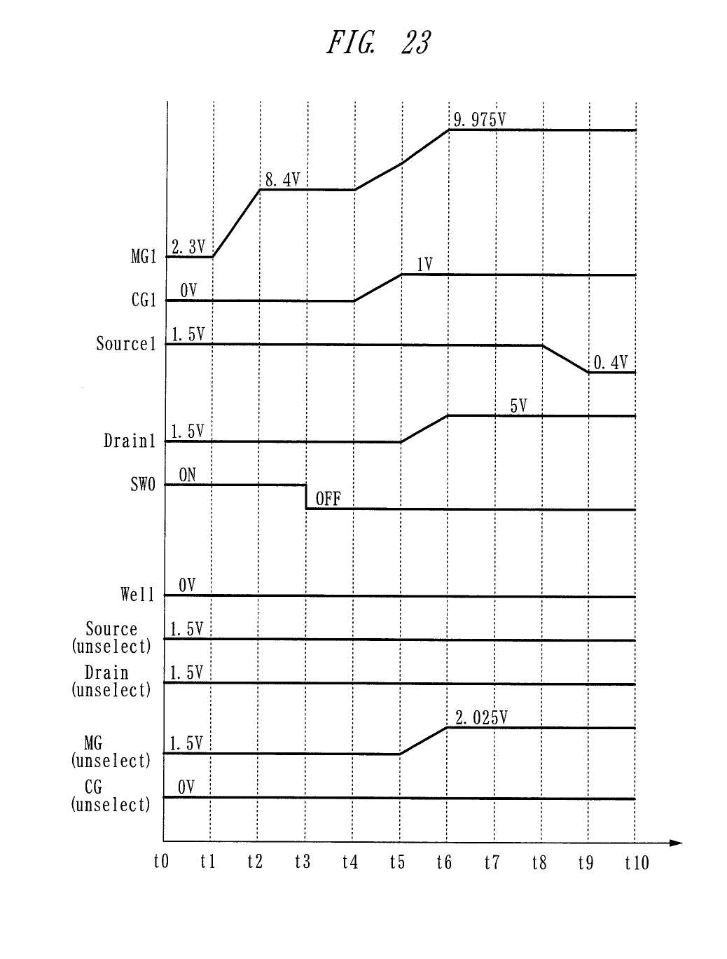

The connecting region of the control circuit and the memory cell array of the nonvolatile semiconductor memory device according to the fourth embodiment will be described with reference to FIG. 22. FIG. 22 shows an equivalent circuit of the switch transistor region formed between the memory gate arranged in the memory cell array and the control circuit.

Metal wirings MLa, MLb, MLc, MLd, MLe, MLf, MLg, and MLh are connected to the memory gates via a switch transistor region SW, and all of the memory gates can be set to be in the floating state at the same time by setting a switch transistor SW0 formed in the switch transistor region SW to be in the OFF state.

FIG. 23 shows a part of a timing diagram describing the programming operation in the nonvolatile semiconductor memory device according to the fourth embodiment. Note that the timing diagram shows the case to boost the memory gate by applying voltages to the control gate and the drain diffusion layer in the selected memory cell similar to the above-described third embodiment, and the effect of the manner is also same with that of the above-described third embodiment.

However, since the number of stages of the switch transistor region SW is one stage in the fourth embodiment, all of memory gates become in the floating state at the same time when the switch transistor SW0 formed in the switch transistor region SW is set to be in the OFF state. By using this manner, the memory gate in the unselected memory cell is also boosted according to the capacitive coupling ratio between the memory gate and the drain diffusion layer. Note that the unselected memory cell assumed here is, for example, the memory cell “C” shown in the above-described FIG. 6 and the like, and while the same voltage with the selected memory cell is applied to the drain diffusion layer, the voltage of the unselected memory cell is applied to the memory gate, the control gate, and the source diffusion layer except for the drain diffusion layer.

When focusing on the unselected memory gate (MG(unselect)), first, 1.5 V is applied to the unselected memory gate from time t0 to time t3. At the time t3, the unselected memory gate (MG(unselect)) becomes the floating state by setting the switch transistor SW0 to the OFF state. From time t4 to time t5, while the voltage applied to the selected control gate (CG1) is increased from 0 V to 1 V, the potential of the unselected control gate (CG(unselect)) does not change, and therefore, the unselected memory gate (MG(unselect)) is not boosted. From the time t5 to time t6, the voltage applied to the selected drain diffusion layer (Drain1) is increased from 1.5 V to 5 V, so that the unselected memory gate (MG(unselect)) is boosted from 1.5 V to about 2.0 V, thereby capable of applying the desired voltage shown in the above-described Table 1 to the unselected memory gate (MG(unselect)).

Also, although not illustrated, a negative voltage is applied to the unselected control gate (CG(unselect)) at time t0, and a positive voltage is applied to the unselected control gate (CG(unselect)) at the time t3 or later in a range of not causing the miss-programming, thereby capable of adjusting the potential of the unselected memory gate (MG(unselect)).

Therefore, although the power supply voltage for the unselected memory gate is provided to apply a voltage to the unselected memory gate in the above-described first embodiment, the voltage of 2.0 V applied to the unselected memory gate is provided by using only an existing power supply voltage for 1.5 V according to the fourth embodiment, thereby capable of scaling down the area size of the power supply circuit compared to the above-described first embodiment. Further, the number of stages of the switch transistor region SW is reduced from eight stages to one stage, thereby capable of scaling down a layout area size.

### Fifth Embodiment

A nonvolatile semiconductor memory device according to a fifth embodiment is similar to the above-described fourth embodiment except for a base voltage applied to the drain diffusion layer at time t0 and the order of the voltages respectively applied to the control gate in the selected memory cell, the drain diffusion layer in the selected memory cell, and the memory gate in the unselected memory cell which are different from those of the above-described fourth embodiment.

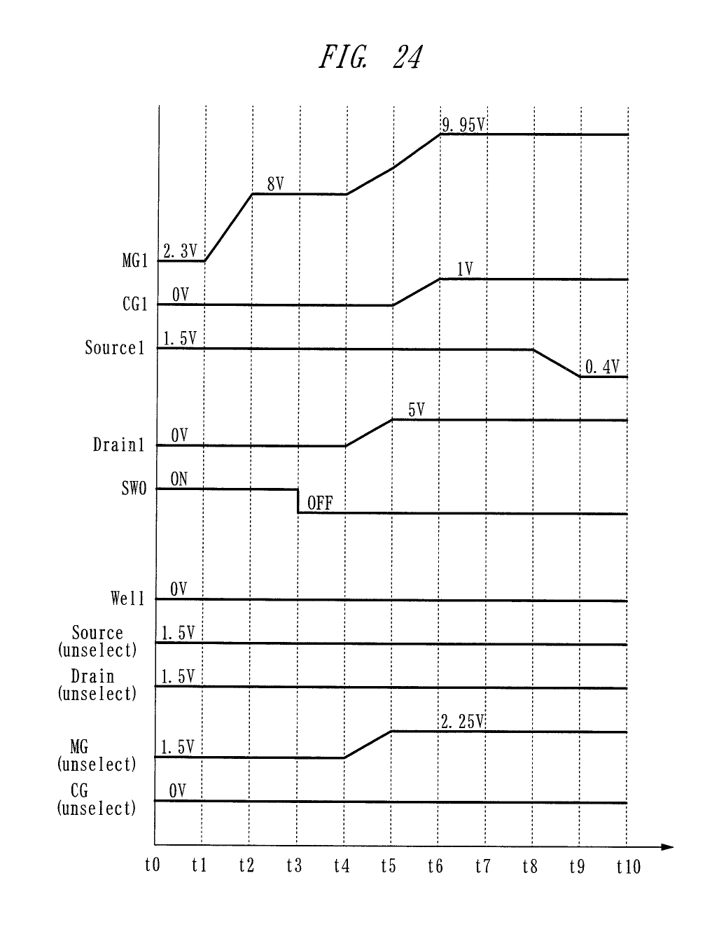

FIG. 24 shows a part of a timing diagram describing a programming operation in the nonvolatile semiconductor memory device according to the fifth embodiment.

First, at time t0, the voltages of the unselected memory cell shown in the above-described Table 1 are applied to the selected memory gate (MG1), the selected control gate (CG1), and the selected source diffusion layer (Source1) in the selected memory cell, respectively. Also, a voltage applied to the selected drain diffusion layer (Drain1) is 0 V. Here, the switch transistor SW0 is in the ON state for supplying the voltage to each of memory gates.

Next, at time t1, the voltage applied to the selected memory gate (MG1) is started to be increased, and the voltage becomes 8 V at time t2. At time t3, the switch transistor SW0 is set to be in the OFF state so that all of memory gates become the floating state at the same time. From time t4 to time t5, the voltage applied to the selected drain diffusion layer (Drain1) is increased from 0 V to 5 V. At this time, the unselected memory gate (MG(unselect)) is boosted from 1.5 V to substantially 2.25 V.

Subsequently, from time t5 to time t6, the voltage applied to the selected control gate (CG1) is increased from 0 V to 1 V. By these operations of the time t4 to the time t6, the potential of the selected memory gate (MG1) is boosted from 8 V to substantially 10 V. Here, the selected control gate (CG1) becomes the OFF state because the voltage applied to the selected source diffusion layer (Source1) is higher than the voltage applied to the selected control gate (CG1) in this voltage application state, and therefore, a current does not flow to the channel region.

From time t8, the voltage applied to the selected source diffusion layer (Source1) is decreased, and the voltage is decreased to desirably 0.4 V at time t9. The programming operation is started by a current flow to the channel region in this voltage application state.

In this manner, according to the fifth embodiment, although the voltage applied to the drain diffusion layer (Drain1) is increased earlier than that of the selected control gate (CG1), since the voltage in the unselected state is applied to the selected control gate (CG1) at the time t0, the current does not flow to the channel region, thereby capable of increasing the potential of the selected drain diffusion layer (Drain1) from 0 V.

As a result, the voltage applied to the selected memory gate (MG1) at time t0 can be reduced by increasing the boosting voltage of the selected memory gate (MG1), thereby capable of scaling down the area size of the power supply circuit. Further, the voltage applied to the unselected memory gate (MG(unselect)) can be boosted from 2.0 V to desirably about 2.3 V by using only the existing power supply voltage for 1.5 V, thereby capable of scaling down the area size of the power supply circuit.

### Sixth Embodiment

A nonvolatile semiconductor memory device according to a sixth embodiment has the split-gate-type MONOS memory cell as a memory cell similarly to the above-described first embodiment. However, a manufacturing method of the switch transistor is different from that of the above-described first embodiment. Although the gate electrode of the switch transistor is formed of the first conductive film (for example, a polysilicon film) on the same layer with the control gate in the above-described first embodiment, the gate electrode of the switch transistor of the sixth embodiment is formed by a second conductive film (for example, a polysilicon film) on the same layer with the memory gate in the sixth embodiment. Note that the connecting region between the control circuit and the memory gate arranged in the memory cell array, the timing diagram in the programming operation, and others are same with those of the above-described first embodiment, and the boosting effect is also same with that of the above-described first embodiment. Also, since only the manufacturing method of the switch transistor is different from the above-described first embodiment, the configuration of the memory cell array and the cross-sectional structure of the memory cell are same with the plan view of principal part of the semiconductor substrate shown in FIG. 2 and the cross-sectional views of principal part of the semiconductor substrate shown in FIG. 3 to FIG. 5 of the above-described first embodiment, respectively.

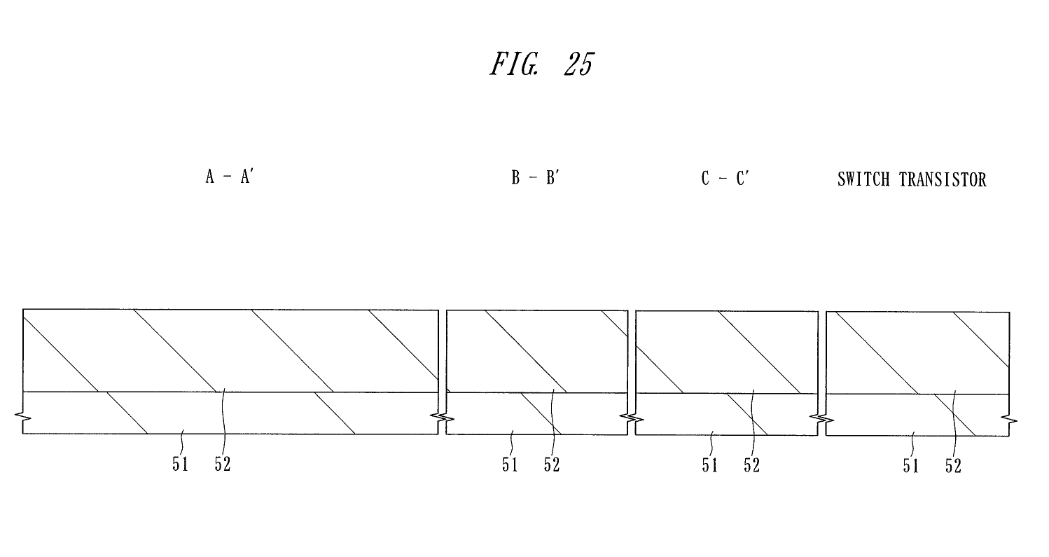

A manufacturing method of the nonvolatile semiconductor memory device according to the sixth embodiment will be described with reference to FIG. 25 to FIG. 30. FIG. 25 to FIG. 30 show cross-sectional views of principal parts of the split-gate-type MONOS memory cell and the switch transistor, and cross-sectional views of principal parts along the line A-A′, the line B-B′, and the line C-C′ shown in the above-described FIG. 2 are shown for the split-gate-type MONOS memory cell.

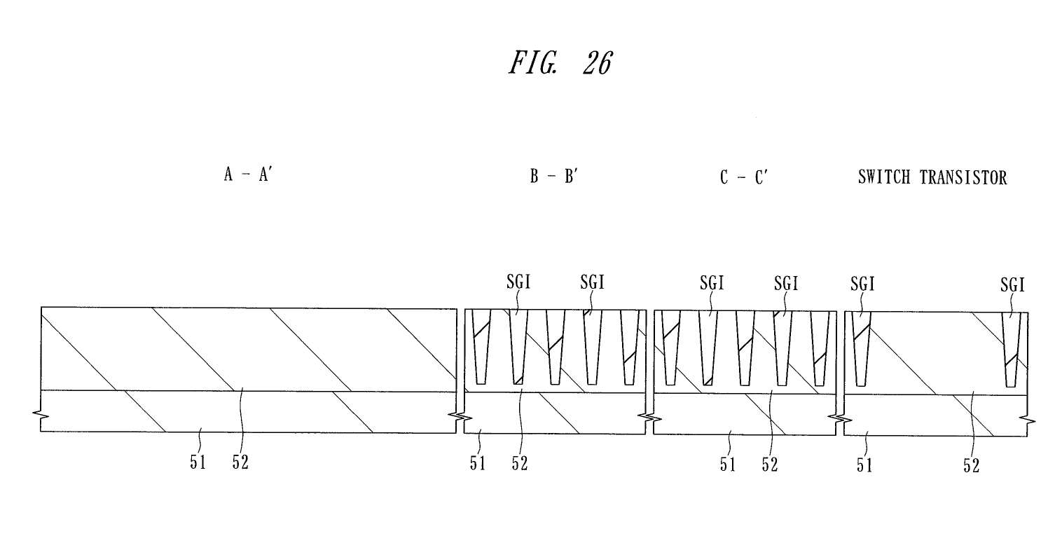

First, as shown in FIG. 25, after preparing a semiconductor substrate 51 and forming a p-type well 52 similarly to the above-described first embodiment, for example, a trench-type device isolation portion SGI, an active region arranged so as to be surrounded by SGI, and the like are formed on the main surface of the semiconductor substrate 51 as shown in FIG. 26.

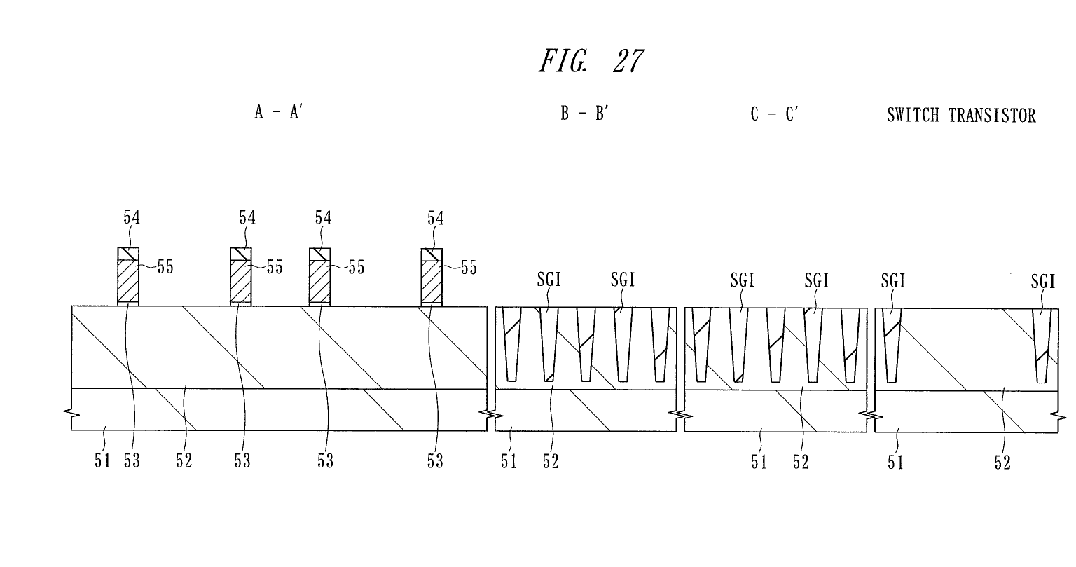

Next, as shown in FIG. 27, a p-type semiconductor region (an illustration thereof is omitted) for forming a channel of an nMIS for control and a switch transistor is formed by ion implantation of a p-type impurity, for example, boron to the main surface of the semiconductor substrate 51. Then, a gate insulator film 53, for example, formed of a silicon oxide film and having a thickness of 2.5 nm or less is formed on the main surface of the semiconductor substrate 51 by applying an oxidation process to the semiconductor substrate 51. Subsequently, a first conductive film, for example, formed of a polysilicon film and having an impurity concentration of about 2×10²⁰ cm⁻³ and a silicon oxide film 54 functioning as a hard mask are sequentially deposited on the main surface of the semiconductor substrate 51. The first conductive film is formed by CVD method, and its film thickness can be exemplified as, for example, about 150 to 250 nm. Subsequently, after processing the silicon oxide film 54 by using a photo resist pattern as a mask, the first conductive film is processed by using the processed silicon oxide film 54 as a mask, thereby forming a control gate 55. A gate length of the control gate 55 is, for example, about 50 to 200 nm.

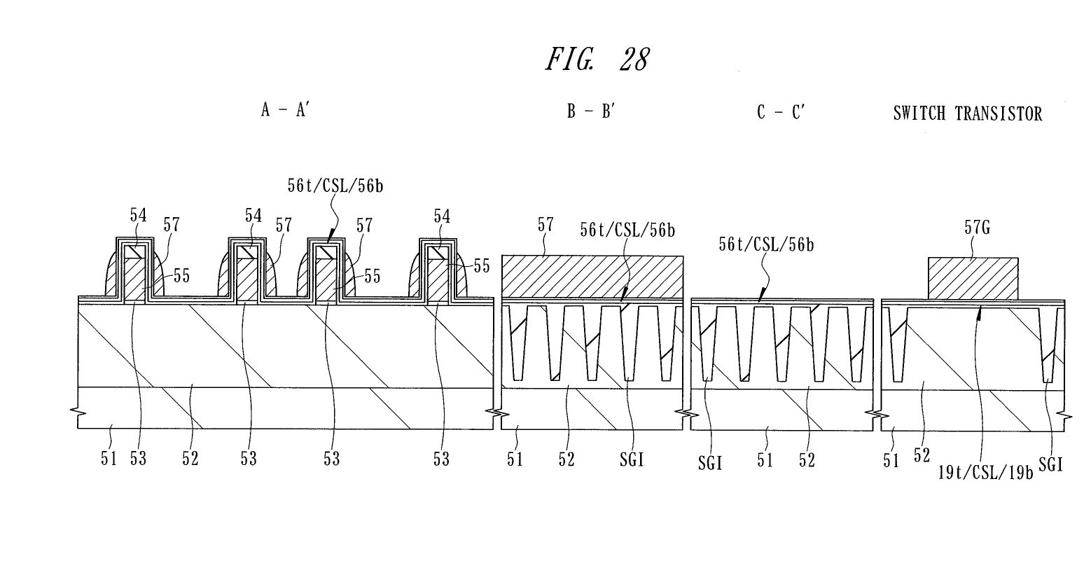

Next, as shown in FIG. 28, a semiconductor region (an illustration thereof is omitted) for forming a channel of an nMIS for memory and a switch transistor is formed by ion implantation of an n-type impurity or a p-type impurity to the main surface of the semiconductor substrate 51. Then, for example, an insulator film 56b made of a silicon oxide film, a charge storing layer CSL made of a silicon nitride film, and an insulator film 56t formed of a silicon oxide film are sequentially deposited on the main surface of the semiconductor substrate 51. The insulator film 56b is formed by thermal oxidation method and a film thickness of the insulator film 56b can be exemplified as, for example, about 1 to 10 nm. The charge storing layer CSL is formed by CVD method and a film thickness of the charge storing layer CSL can be exemplified as, for example, about 5 to 20 nm. And the insulator film 56t is formed by CVD method and a film thickness of the insulator 56t can be exemplified as, for example, about 5 to 15 nm. The insulator films 56b and 56t and the charge storing layer CSL function as a gate insulator film of the nMIS for memory and a gate insulator film of the switch transistor which will be formed later in addition to a function of holding charges.

Since a configuration of each film of the insulator films 56b and 56t and the charge storing layer CSL is changed depending on a using method of a manufactured semiconductor device, only typical configurations and values are exemplified here. However, they are not limited to the above-described configurations and values.

Next, a second conductive film, for example, formed of a polysilicon film and having an impurity concentration of about 2×10²⁰ cm⁻³ is deposited on the main surface of the semiconductor substrate 51. The second conductive film is formed by CVD method, and its film thickness can be exemplified as, for example, about 30 to 150 nm. Subsequently, an etch-back is performed to the second conductive film by using anisotropic dry-etching method, thereby forming sidewalls 57 on gates of both side surfaces of the control gate 55 interposing the insulator films 56b and 56t and the charge storing layer CSL and forming a gate 57G of the switch transistor at the same time. The etch-back is performed to the second conductive film by using the insulator film 56t as an etching stopper layer in the step of forming the sidewall 57 and the gate 57G. For not receiving damage caused by the etch-back in the insulator 56t and the charge storing layer CSL under the insulator 56t, an etching condition with low damage is desired to be set. If the insulator 56t and the charge storing layer CSL are damaged, a property deterioration of the memory cell such as a deterioration of the charge holding property occurs.

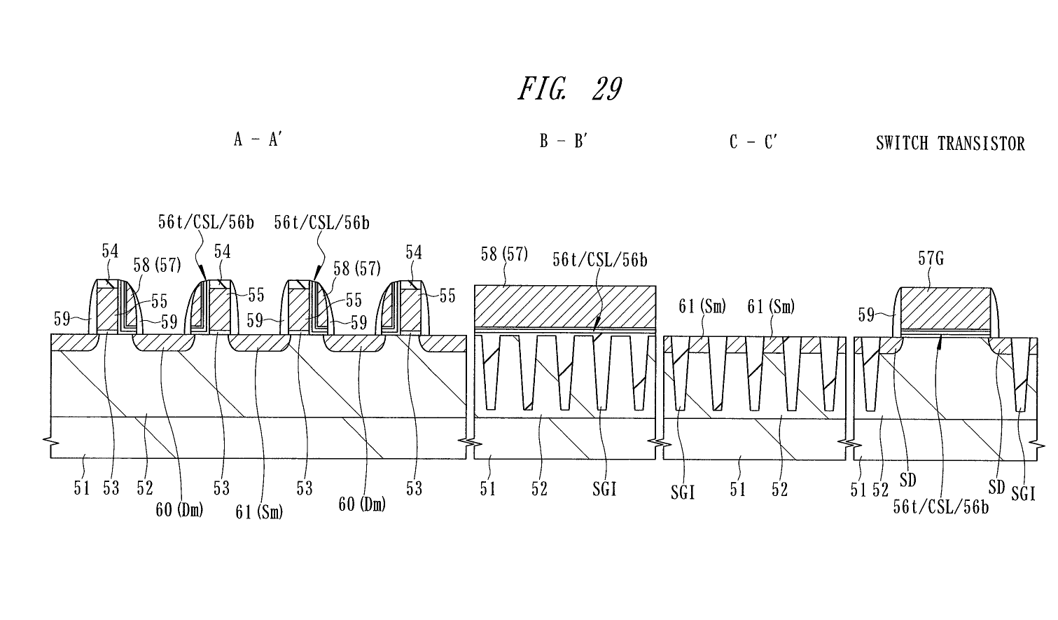

Next, as shown in FIG. 29, a part of the sidewall 57 exposed from the photo resist pattern is etched by using the photo resist pattern as a mask, thereby forming a memory gate 58 formed by the sidewall 57 on only one side of the sidewalls of the control gate 55. A gate length of the memory gate 58 is, for example, about 30 to 150 nm.

Next, with remaining the insulator films 56b and 56t and the charge storing layer CSL between the control gate 55 and the memory gate 58 and between the semiconductor substrate 51 and the memory gate 58, an etching is selectively performed to the insulator films 56b and 56t and the charge storing layer CSL in another region of the remaining part.

Next, after depositing an insulator film, for example, formed of a silicon oxide film and having a thickness of about 80 nm, by plasma CVD method on the main surface of the semiconductor substrate 51, an etch-back is performed to this insulator film by using anisotropic dry-etching method, thereby forming a sidewall 59 on each of one side surface of the control gate 55, one side surface of the memory gate 58, and both side surfaces of the gate 57G of the switch transistor. A spacer length of the sidewall 59 is, for example, about 60 nm. In this manner, the sidewall 59 can cover an exposed side surface of the gate insulator 53 between the control gate 55 and the semiconductor substrate 51 and an exposed side surface of the insulator films 56b and 56t and the charge storing layer CSL between the memory gate 58 and the semiconductor substrate 51.

Next, n⁺-type semiconductor regions 60 and 61 are formed so as to be self-aligned with the control gate 55 and the memory gate 58 on the main surface of the semiconductor substrate 51 by ion implantation of an n-type impurity, for example, arsenic or phosphorus to the main surface of the semiconductor substrate 51 with using the sidewall 59 as a mask. Thereby, there are formed a drain diffusion layer Dm formed by the n⁺-type semiconductor region 60 and a source diffusion layer Sm formed by the n⁺-type semiconductor region 61. At the same time, a source/drain diffusion layer SD of the switch transistor is formed.

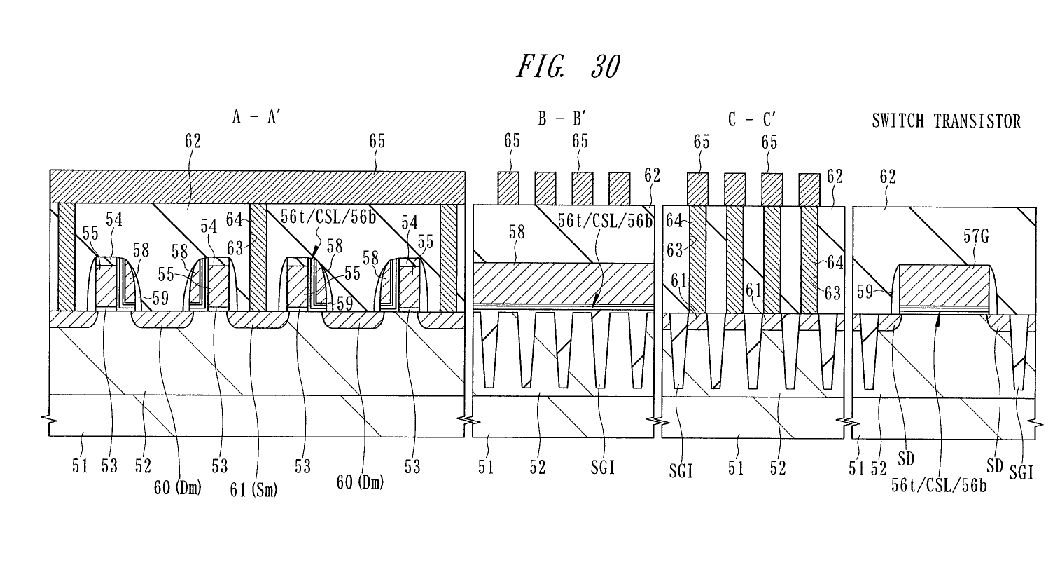

Next, as shown in FIG. 30, an interlayer insulator film 62 formed of, for example, a silicon nitride film and a silicon oxide film is formed by CVD method on the main surface of the semiconductor substrate 51. Subsequently, after forming a contact hole 63 in the interlayer insulator film 62, a plug 64 is formed inside of the contact hole 63. The plug 64 has, for example, a barrier film which is relatively thin and is formed by a stacked film of titanium and titanium nitride, and an conductive film which is relatively thick and made of tungsten, aluminum, or the like being surrounded by the barrier film. And then, a metal wiring 65 of the first layer made of, for example, tungsten, aluminum, cupper, or the like is formed on the interlayer insulator 62. After this step, the nonvolatile semiconductor memory device is manufactured through a regular manufacturing process of a semiconductor device.

In this manner, according to the sixth embodiment, since the gate insulator film of the switch transistor is formed by the insulator films 56b and 56t and the charge storing layer CSL, a dielectric breakdown voltage of the switch transistor can be improved compared to the above-described first embodiment in which the gate insulator of the switch transistor is formed by the silicon oxide film.

### Seventh Embodiment

A nonvolatile semiconductor memory device according to a seventh embodiment has a memory gate formed by a polysilicon film to which a p-type impurity is injected, and an erasing operation is performed by applying a positive voltage of about 12 V to the memory gate to inject holes from the memory gate. Note that, a connecting region between the memory gates which are arranged in a memory cell array and a control circuit, a timing diagram in a programming operation, and the like are same with those of the above-described first embodiment, and a boosting effect in a selected memory gate/unselected memory gate caused by the programming operation is also same with that of the above-described first embodiment. Also, each of a configuration of the memory cell array, a cross section structure of a memory cell, a cross section structure of a switch transistor, and the like is same with the plan view of principle part of the semiconductor substrate shown in FIG. 2 and the plan views of principle parts of the semiconductor substrate shown in FIG. 3 to FIG. 5 of the above-described first embodiment. A manufacturing method is same with that of the above-described first embodiment except for using, for example, a polysilicon film injected with a p-type impurity instead of a polysilicon film injected with an n-type impurity for the second conductive film forming the memory gate shown in the above-described first embodiment.

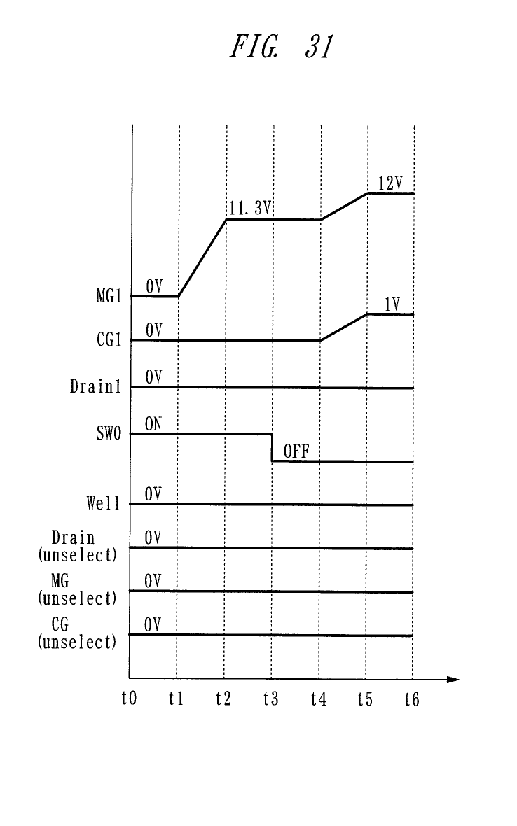

Voltage conditions of a programming operation, an erasing operation, and a reading operation of the memory cell according to the seventh embodiment will be shown in Table 2. Since the programming operation is same with that of the above-described first embodiment, only the erasing operation will be described. FIG. 31 shows a part of a timing diagram describing the erasing operation in the nonvolatile semiconductor memory device according to the seventh embodiment.

TABLE 2

| | MG | CG | Drain | Source | |
|---|---|---|---|---|---|
| | (select) | (select) | (select) | (select) | Well |
| Read | 0 V | 1.5 V | 0 V | 1.5 V | 0 V |
| Program | 10 V | 1 V | 5 V | 0.4 V | 0 V |
| Erase | 12 V | 1 V | 0 V | OPEN | 0 V |

| | MG | | CG | Drain | Source |
|---|---|---|---|---|---|
| | (unselect) | | (unselect) | (unselect) | (unselect) |
| Read | 0 | V | 0 V | 0 V | 0 V |
| Program | 2-2.3 | V | 0 V | 1.5 V | 1.5 V |
| Erase | 0 | V | 0 V | 0 V | OPEN |

As shown in FIG. 31, at time t0, a selected memory gate (MG1), a selected control gate (CG1), a source diffusion layer (Source1), and a drain diffusion layer (Drain1) in the selected memory cell are in the voltage conditions of the unselected memory cell shown in FIG. 2. Here, a switch transistor SW0 is in the ON state for supplying a voltage to each of memory gates.

Next, at time t1, a voltage applied to the selected memory gate (MG1) is started to be increased, and the voltage becomes 11.3 V at time t2. At time t3, the switch transistor SW0 is set to be in the OFF state so that all of memory gates become the floating state at the same time. From time t4 to time t5, the voltage applied to the selected control gate (CG1) is increased from 0 V to 1 V. By this operation, the potential of the selected memory gate (MG1) is boosted from 11.3 V to 12 V, thereby starting the erasing operation.

In this manner, according to the seventh embodiment, since the memory gate can be boosted by the control gate not only in the programming operation but also in the erasing operation, a generated voltage can be reduced also in the power supply circuit in the erasing operation, thereby capable of scaling down the area size of the power supply circuit.

### Eighth Embodiment

In an eighth embodiment, a structure of a switch transistor is different from the structure of the switch transistor in the above-described first embodiment.

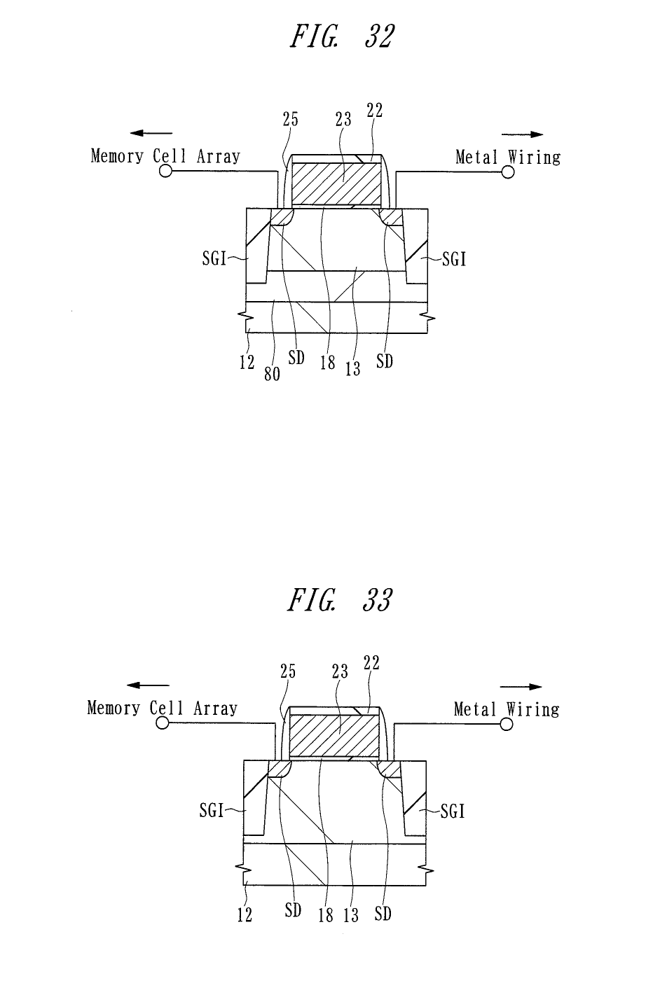

FIG. 32 is a cross-sectional view of principal part of the semiconductor substrate showing one example of the structure of the switch transistor in a case of using a negative voltage for the memory operation. As shown in FIG. 32, an n-type semiconductor region 80 is formed on the semiconductor substrate 12 so as to surround the p-type well 13, thereby capable of blocking a diode forward leakage current when the negative voltage is applied.

FIG. 33 is a cross-sectional view of principal part of the semiconductor substrate showing one example of the structure of the switch transistor in a case of not using a negative voltage for the memory operation according to the eighth embodiment. Since a negative voltage is not applied, the n-type semiconductor region 80 is unnecessary.

### Ninth Embodiment

In a ninth embodiment, a structure of a split-gate-type MONOS memory cell is different from the structure of the split-gate-type MONOS memory cell in the above-described first embodiment. That is, a so-called twin MONOS memory cell having memory gates on both side surfaces of the control gate is exemplified in the ninth embodiment.

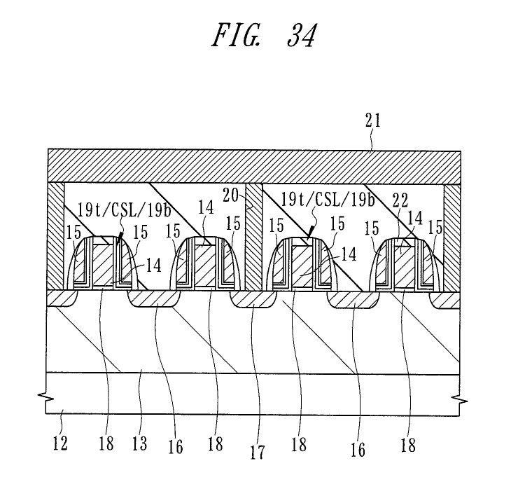

FIG. 34 is a cross-sectional view of principal part of the semiconductor substrate showing one example of the structure of the twin MONOS memory cell according to the ninth embodiment. In the programming operation, the voltage is applied also to the selected memory gate commonly using the selected control gate on the contact hole 20 side. The programming operation except for this manner is same with that of the above-described first embodiment. A manufacturing method is same with that of the above-described first embodiment except for, for example, not removing the sidewall 24 on the one side but remaining the sidewall 24 on both side surfaces of the control gate 14 to make the memory gate 15 in forming of the memory gate described in the above-described first embodiment.

In this manner, the same effect with the above-described first embodiment can be obtained also in the twin MONOS memory cell according to the ninth embodiment.

In the foregoing, the invention made by the inventors of the present invention has been concretely described based on the embodiments. However, it is needless to say that the present invention is not limited to the foregoing embodiments and various modifications and alterations can be made within the scope of the present invention.

The nonvolatile semiconductor memory device of the present invention can be applied to a memory device for an embedded micro computer for a consumer use, an OA use, an in-vehicle use, an industrial use, or the like.

What is claimed is:

1. A nonvolatile semiconductor memory device comprising a memory cell, the memory cell including a first field-effect transistor formed in a first region on a main surface of a semiconductor substrate and a second field-effect transistor formed in a second region on the main surface of the semiconductor substrate and adjacent to the first field-effect transistor, wherein
the memory cell is composed of: a first insulator film including a charge storing layer having a function of storing charges formed in the first region; a first gate of the first field-effect transistor formed with interposing the first insulator film; a second insulator film formed in the second region; a second gate of the second field-effect transistor formed with interposing the second insulator film; a third insulator film formed between the first gate and the second gate; a source diffusion layer; and a drain diffusion layer,
each of the first gate, the second gate, the source diffusion layer, and the drain diffusion layer is connected to a control circuit for controlling potential,
the control circuit operates so as to supply a first potential to the first gate, a second potential to the second gate, a third potential to the drain diffusion layer, and a fourth potential to the source diffusion layer,
thereafter, the control circuit operates so as to set the first gate to be in a floating state, and
thereafter, the control circuit operates so as to make the first gate have a fifth potential which is higher than the first potential and to supply a sixth potential which is higher than the second potential to the second gate.

2. The nonvolatile semiconductor memory device according to claim 1, wherein
the first insulator is a stacked film configured with a lower-layer insulator film, the charge storing layer, and an upper-layer insulator film.

3. The nonvolatile semiconductor memory device according to claim 1, wherein
the third insulator film is an insulator film on a same layer with the first insulator film.

4. The nonvolatile semiconductor memory device according to claim 1, wherein
the charge storing layer is a silicon nitride film.

5. The nonvolatile semiconductor memory device according to claim 1, wherein,
after setting the first gate to be in the floating state,
the control circuit operates so as to supply a seventh potential which is higher than the third potential to the drain diffusion layer.

6. The nonvolatile semiconductor memory device according to claim 5, wherein
after setting the first gate to be in the floating state,
the control circuit first operates so as to supply the sixth potential to the second gate, and
thereafter, the control circuit operates so as to supply the seventh potential to the drain diffusion layer.

7. The nonvolatile semiconductor memory device according to claim 5, wherein
after setting the first gate to be in the floating state,
the control circuit first operates so as to supply the seventh potential to the drain diffusion layer, and
thereafter, the control circuit operates so as to supply the sixth potential to the second gate, and to set the third potential to be lower than the fourth potential.

8. The nonvolatile semiconductor memory device according to claim 1, wherein
a switch transistor for setting the first gate to be in the floating state is provided between the control circuit and a memory cell array, and
a gate of the switch transistor is formed of a same material with that of the second gate.

9. The nonvolatile semiconductor memory device according to claim 1, wherein
a switch transistor for setting the first gate to be in the floating state is provided between the control circuit and a memory cell array, and
a gate insulator film of the switch transistor is formed by a same process with that of the first insulator film, and
a gate of the switch transistor is formed of a same material with that of the first gate.

10. A nonvolatile semiconductor memory device comprising:
a first memory cell including a first field-effect transistor formed in a first region on a main surface of a semiconductor substrate and a second field-effect transistor formed in a second region on the main surface of the semiconductor substrate and adjacent to the first field-effect transistor; and
a second memory cell including a third field-effect transistor formed in a third region on the main surface of the semiconductor substrate and a fourth field-effect transistor formed in a fourth region on the main surface of the semiconductor substrate and adjacent to the third field-effect transistor, wherein
the first memory cell is composed of: a first insulator film including a first charge storing layer having a function of storing charges formed in the first region; a first gate of the first field-effect transistor formed with interposing the first insulator film; a second insulator film formed in the second region; a second gate of the second field-effect transistor formed with interposing the second insulator film; a third insulator film formed between the first gate and the second gate; a first source diffusion layer; and a first drain diffusion layer,
each of the first gate, the second gate, the first source diffusion layer, and the first drain diffusion layer is connected to a control circuit for controlling potential,
the second memory cell is composed of: a fourth insulator film including a second charge storing layer having a function of storing charges formed in the third region; a third gate of the third field-effect transistor formed with interposing the fourth insulator; a fifth insulator film formed in the fourth region; a fourth gate of the fourth field-effect transistor formed with interposing the fifth insulator; a sixth insulator film formed between the third gate and the fourth gate; a second source diffusion layer; and a second drain diffusion layer,
each of the third gate, the fourth gate, the second source diffusion layer, and the second drain diffusion layer is connected to the control circuit for controlling potential,
the control circuit operates so as to supply a first potential to the first gate, a second potential to the second gate, a third potential to the first drain diffusion layer, and a fourth potential to the first source diffusion layer,
the control circuit further operates so as to supply a fifth potential to the third gate, a sixth potential to the fourth gate, a seventh potential to the second drain diffusion layer, and a eighth potential to the second source diffusion layer,
thereafter, the control circuit operates so as to set the first gate and the third gate to be in a floating state at the same time,
thereafter, the control circuit operates so as to supply a tenth potential which is higher than the second potential to the second gate and so as to supply an eleventh potential which is higher than the third potential to the first drain diffusion layer to make the first gate have a ninth potential which is higher than the first potential, and
the control circuit further operates so as to supply a thirteenth potential which is higher than the sixth potential to the fourth gate and so as to supply a fourteenth potential which is higher than the seventh potential to the second drain diffusion layer to make the third gate have a twelfth potential which is higher than the fifth potential.

11. The nonvolatile semiconductor memory device according to claim 10, wherein
the first potential is equal to the fifth potential so that electrons are injected to the first charge storing layer and the second charge storing layer by the operation of the control circuit to program information to the first memory cell and the second memory cell at the same time.

12. The nonvolatile semiconductor memory device according to claim 10, wherein
the first gate, the second gate, the third gate, and the fourth gate exist in a same block in a memory cell array,
the first potential is higher than the fifth potential so that electrons are injected to the first charge storing layer by the operation of the control circuit to program information to the first memory cell and electrons are not injected to the second charge storing layer not to program information to the second memory cell.

13. The nonvolatile semiconductor memory device according to claim 12, wherein
the first drain diffusion layer and the second drain diffusion layer are electrically connected to each other, the third potential is equal to the seventh potential, and the eleventh potential is equal to the fourteenth potential.

14. The nonvolatile semiconductor memory device according to claim 10, wherein
a switch transistor for setting the first gate and the third gate to be in the floating state is provided between the control circuit and a memory cell array, and
a gate of the switch transistor is electrically connected to the first gate and the third gate, and sets a plurality of lines of gates including the first gate and the third gate to be in the floating state at the same time.

15. The nonvolatile semiconductor memory device according to claim 10, wherein
a power supply circuit for generating the twelfth potential does not exist outside of a memory cell array.

16. A nonvolatile semiconductor memory device comprising a memory cell, the memory cell including a first field-effect transistor formed in a first region on a main surface of a semiconductor substrate and a second field-effect transistor formed in a second region on the main surface of the semiconductor substrate and adjacent to the first field-effect transistor, wherein
the memory cell is composed of: a first insulator film including a charge storing layer having a function of storing charges formed in the first region; a first gate of the first field-effect transistor formed with interposing the first insulator film; a second insulator film formed in the second region; a second gate of the second field-effect transistor formed with interposing the second insulator film; a third insulator film formed between the first gate and the second gate; a source diffusion layer; and a drain diffusion layer,
each of the first gate, the second gate, the source diffusion layer, and the drain diffusion layer is connected to a control circuit for controlling potential,
the control circuit operates so as to supply a first potential to the first gate, a second potential to the second gate, a third potential to the drain diffusion layer, and a fourth potential to the source diffusion layer upon injecting holes from the first gate to the charge storing layer,
thereafter, the control circuit operates so as to set the first gate to be in the floating state, and
thereafter, the control circuit operates so as to supply a sixth potential which is higher than the second potential to the second gate to make the first gate have a fifth potential which is higher than the first potential.
